(19) United States
(12) Patent Application Publication
(10) Pub. No.: US 2025/0048637 A1
(43) Pub. Date: Feb. 6, 2025

(54) APPARATUS AND METHODS FOR INCREASING CROSS BIT LINE PITCH IN NON-VOLATILE MEMORY CONTROL CIRCUITS

(71) Applicant: Western Digital Technologies, Inc., San Jose, CA (US)

(72) Inventor: Hiroki Yabe, Yokohama (JP)

(73) Assignee: Western Digital Technologies, Inc., San Jose, CA (US)

(21) Appl. No.: 18/365,394

(22) Filed: Aug. 4, 2023

(51) Int. Cl. H10B 43/40; H01L 23/00; H01L 25/065; H01L 25/18; H10B 41/27; H10B 41/41; H10B 43/27; H10B 80/00

(52) U.S. Cl. CPC H10B 43/40; H01L 24/08; H01L 25/0657; H01L 25/18; H10B 41/27; H10B 41/41; H10B 43/27; H10B 80/00; H01L 2224/08145; H01L 2924/1431; H01L 2924/14511

(57) ABSTRACT

An apparatus is provided that includes a three dimensional array of non-volatile memory cells, and a control circuit configured to control the three dimensional memory array. The control circuit includes a first number of sense amplifier tiers, each having sense amplifiers arranged along a first axis, a second number of bit line switch regions, each having bit line switches, each bit line switch coupled to a corresponding one of the sense amplifiers, the second number greater than the first number, and a plurality of cross bit lines routed along an axis parallel to the first axis and arranged along a second axis perpendicular to the first axis, each cross bit line coupled to a corresponding one of the bit line switches. Each bit line switch is configured to selectively couple a corresponding one of the cross bit lines to a corresponding one of the sense amplifiers.

### BACKGROUND

The present technology relates to memory devices. Semiconductor memory devices have become more popular for use in various electronic devices. For example, non-volatile semiconductor memory is used in cellular telephones, digital cameras, personal digital assistants, mobile computing devices, non-mobile computing devices and other devices.

A charge-storing material such as a floating gate or a charge-trapping material can be used in such memory devices to store a charge which represents a program state. For example, a charge-trapping material can be arranged vertically in a three-dimensional (3D) stacked memory array. One example of a 3D memory array is the Bit Cost Scalable (BiCS) architecture which comprises a stack of alternating conductive and dielectric layers.

A memory device includes memory cells which may be arranged in series (e.g., in NAND strings). Each memory cell in a NAND string has a control gate that is coupled to a corresponding word line, and each NAND string is coupled to a corresponding bit line. Each bit line is coupled to a corresponding sense module.

The threshold voltage of each memory cell is controlled by the amount of charge that is retained on the charge storage material. To program a memory cell in a NAND string, one or more program pulses are applied to the word line coupled to the memory cell to change an amount of charge on the charge storage material, and hence change the threshold voltage of the memory cell. To read a memory cell, the corresponding bit line coupled to the NAND string is coupled to a sense module to determine the threshold voltage of the memory cell.

However, various challenges exist in fabricating such memory devices.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 2C and 2D depict different embodiments of integrated memory assemblies.

FIG. 3 is a perspective view of a portion of one embodiment of a monolithic three dimensional memory array.

FIG. 4A is a block diagram of a memory array having two planes.

FIG. 4B depicts a top view of a portion of a block of memory cells.

FIG. 4C depicts a cross sectional view of a portion of a block of memory cells.

FIG. 4D is a cross sectional view of a vertical column of memory cells.

FIG. 4E is a schematic of a plurality of NAND strings showing multiple sub-blocks.

FIG. 5 depicts threshold voltage distributions.

FIG. 6 is a table describing one example of an assignment of data values to data states.

FIG. 7 is a flow chart describing one embodiment of a process for programming non-volatile memory.

FIG. 8 is a circuit diagram of one embodiment of a portion of a memory system.

FIG. 9A depicts a top view of a memory die.

FIG. 9B depicts a top view of a control die.

FIG. 10A shows a portion of a top view of a control die.

FIG. 10B shows a corresponding cross section of an integrated assembly including the control die of FIG. 10A.

FIG. 10C is a detailed view of an example layout of portion of the control die of FIG. 10A.

FIG. 11 is a detailed view of an example layout of a portion of the control die of FIG. 10A.

FIG. 12 is a simplified view of another example layout of a portion of the control die of FIG. 10A.

FIG. 13 is a simplified diagram of a sense amp tier and two bit line switch regions of FIG. 12

FIG. 14 is a flow diagram of an embodiment of a process for fabricating a control die that includes circuits for controlling a memory die including a three dimensional non-volatile memory array.

### DETAILED DESCRIPTION

Some memory systems include a memory die and a control die coupled to the memory die. The memory die includes a three dimensional non-volatile memory array that has non-volatile memory cells. The control die is disposed below the memory die and includes a control circuit configured to control the three dimensional non-volatile memory array. The control circuit includes a “sense amplifier region” that includes sense amplifiers disposed in sense amplifier tiers and arranged along a first axis. The sense amplifier region also includes portions of cross bit lines routed along an axis parallel to the first axis and arranged along a second axis perpendicular to the first axis.

Traditionally, the portions of the cross bit lines in the sense amplifier region are routed above the sense amplifiers, and are disposed at a pitch determined by the number of sense amplifier tiers and the height of the sense amplifier tiers. As the number and height of sense amplifier tiers decreases with advances in integrated circuit technology, the cross bit line pitch decreases, requiring more expensive processing technology as the cross bit line pitch approaches the processing limits.

Technology is described for routing some of the cross bit lines above a region other than the sense amplifier region. Without wanting to be bound by any particular theory, it is believed that the described technology may increase the cross bit line pitch and avoid the need for costly processing techniques.

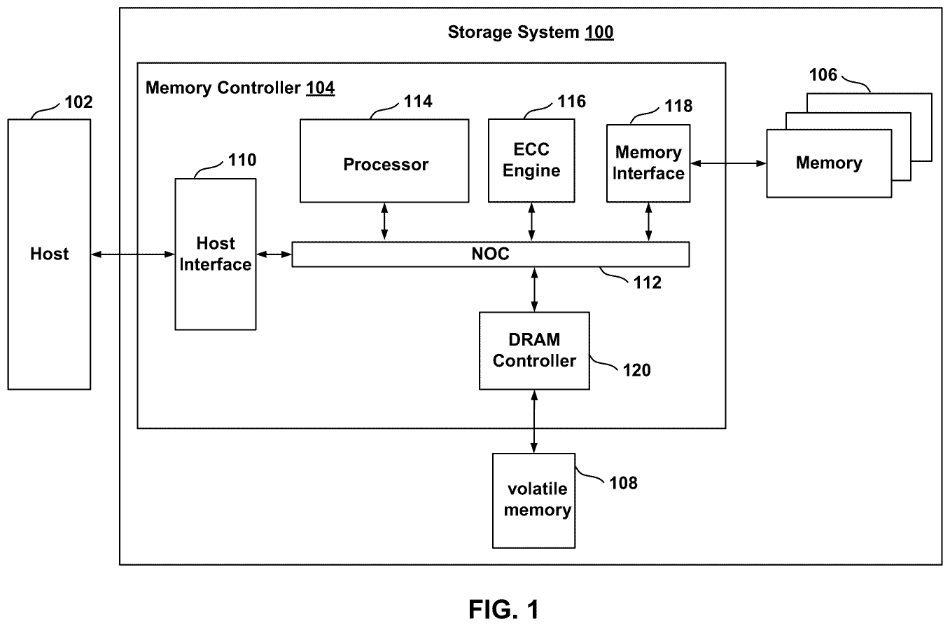

FIG. 1 is a block diagram of an embodiment of a storage system 100 that implements the proposed technology described herein. In an embodiment, storage system 100 is a solid state drive (“SSD”). Storage system 100 also can be a memory card, USB drive or other type of storage system. The proposed technology is not limited to any type of memory system.

Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 104 connected to non-volatile memory 106 and local high speed volatile memory 108 (e.g., DRAM). Local high speed volatile memory 108 is used by memory controller 104 to perform certain functions. For example, local high speed volatile memory 108 stores logical to physical address translation tables (“L2P tables”).

Memory controller 104 includes a host interface 110 that is connected to and in communication with host 102. In an embodiment, host interface 110 implements a NVM Express (NVMe) over PCI Express (PCIe). Other interfaces also can be used, such as SCSI, SATA, etc. Host interface 110 also is connected to a network-on-chip (NOC) 112. A NOC is a communication subsystem on an integrated circuit. In other embodiments, NOC 112 can be replaced by a bus.

Connected to and in communication with NOC 112 is processor 114, error correction code (ECC) engine 116, memory interface 118, and DRAM controller 120. Processor 114 performs the various controller memory operations, such as programming, erasing, reading, and memory management processes. In an embodiment, processor 114 is programmed by firmware. In other embodiments, processor 114 is a custom and dedicated hardware circuit without any software. Processor 114 also implements a translation module, as a software/firmware process or as a dedicated hardware circuit.

ECC engine 116 performs error correction services. For example, ECC engine 116 performs data encoding and decoding, as per the implemented ECC technique. In an embodiment, ECC engine 116 is an electrical circuit programmed by software. For example, ECC engine 116 can be a processor that can be programmed. In other embodiments, ECC engine 116 is a custom and dedicated hardware circuit without any software. In another embodiment, the function of ECC engine 116 is implemented by processor 114.

Memory interface 118 communicates with non-volatile memory 106. In one embodiment, memory interface provides a Toggle Mode interface. Other interfaces can also be used. In some example implementations, memory interface 118 (or another portion of controller 104) implements a scheduler and buffer for transmitting data to and receiving data from one or more memory die.

DRAM controller 120 is used to operate and communicate with local high speed volatile memory 108 (e.g., DRAM). In other embodiments, local high speed volatile memory 108 can be SRAM or another type of volatile memory.

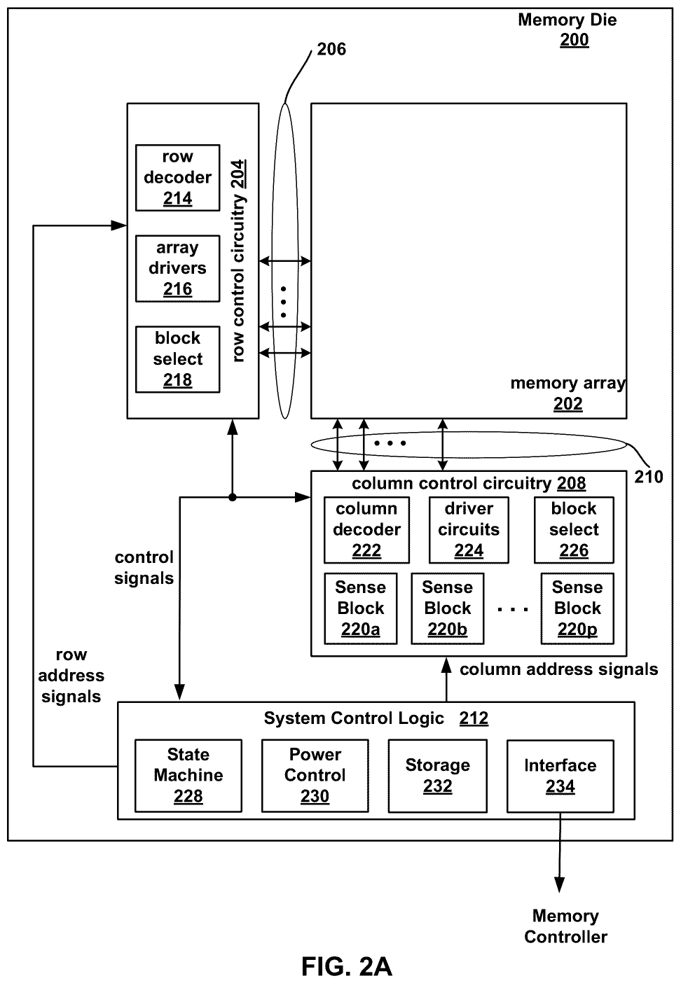

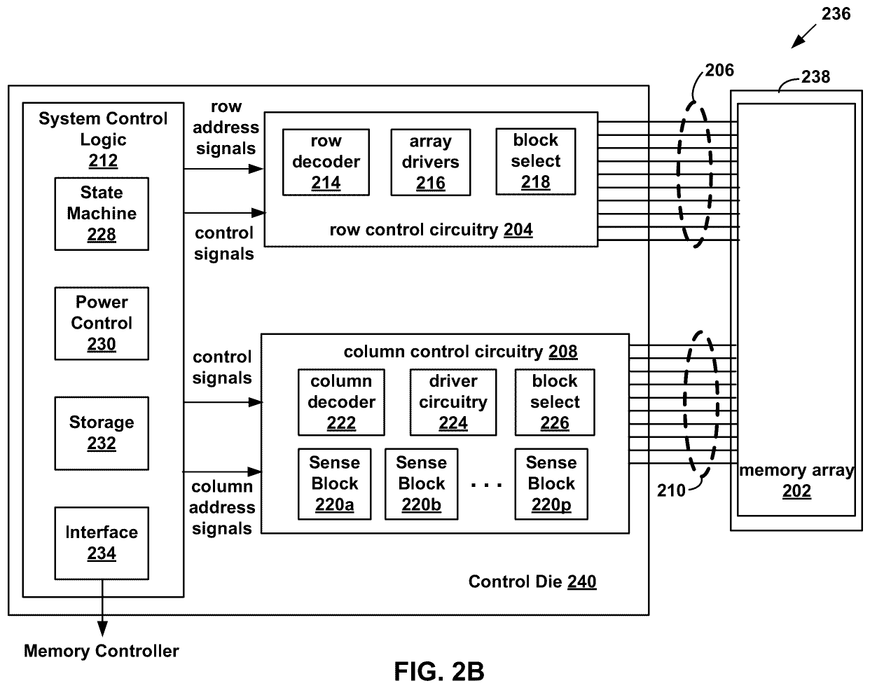

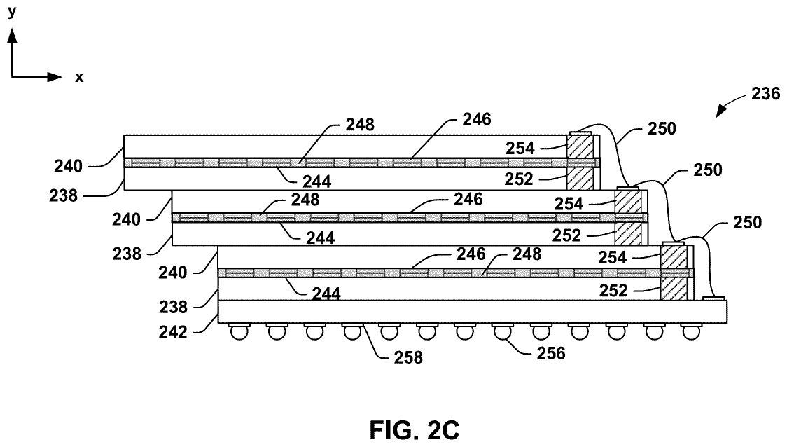

In an embodiment, non-volatile memory 106 includes one or more memory die. FIG. 2A is a functional block diagram of an embodiment of a memory die 200 that includes non-volatile memory 106. Each of the one or more memory die of non-volatile memory 106 can be implemented as memory die 200 of FIG. 2A. The components depicted in FIG. 2A are electrical circuits.

Memory die 200 includes a memory array 202 that can includes non-volatile memory cells, as described in more detail below. The array terminal lines of memory array 202 include the various layer(s) of word lines organized as rows, and the various layer(s) of bit lines organized as columns. However, other orientations also can be implemented.

Memory die 200 includes row control circuitry 204, whose outputs 206 are connected to respective word lines of the memory array 202. Memory die 200 also includes column control circuitry 208, whose input/outputs 210 are connected to respective bit lines of memory array 202. Memory die 200 also includes system control logic circuit 212, which receives data and commands from memory controller 104 and provides output data and status to host 102.

Row control circuitry 204 receives a group of M row address signals and one or more various control signals from system control logic circuit 212, and typically may include such circuits as row decoders 214, array terminal drivers 216, and block select circuitry 218 for both reading and writing (programming) operations. Row control circuitry 204 also may include read/write circuitry.

Column control circuitry 208 includes sense blocks 220 (e.g., sense blocks 220a, 220b, . . . , 220p) that allow one or more pages of data in memory cells of memory array 202 to be read or programmed in parallel. In an embodiment, each sense block 220 includes one or more sense amplifiers. In an embodiment, each bit line of memory array 202 is coupled to a corresponding one of the sense amplifiers of sense blocks 220.

Although only a single block is shown for memory array 202, memory die 200 can include multiple arrays that can be individually accessed. Column control circuitry 208 receives a group of N column address signals and one or more various control signals from system control logic 212, and typically may include such circuits as column decoders 222, array terminal receivers or driver circuits 224, block select circuitry 226, as well as read/write circuitry, and I/O multiplexers.

System control logic 212 receives data and commands from memory controller 104 and provides output data and status to host 102. In some embodiments, system control logic 212 (which includes one or more electrical circuits) includes state machine 228 that provides die-level control of memory operations. In one embodiment, state machine 228 is programmable by software. In other embodiments, state machine 228 does not use software and is completely implemented in hardware (e.g., electrical circuits). In another embodiment, state machine 228 is replaced by a micro-controller or microprocessor, either on or off the memory chip.

System control logic 212 also can include a power control module 230 that controls the power and voltages supplied to the rows and columns of memory array 202 during memory operations and may include charge pumps and regulator circuit for creating regulating voltages. System control logic 212 includes storage 232 (e.g., RAM, registers, latches, etc.), which may be used to store parameters for operating memory array 202.

Commands and data are transferred between memory controller 104 and memory die 200 via memory controller interface 234 (also referred to as a “communication interface”). Memory controller interface 234 is an electrical interface for communicating with memory controller 104. Examples of memory controller interface 234 include a Toggle Mode Interface and an Open NAND Flash Interface (ONFI). Other I/O interfaces can also be used.

In some embodiments, all the elements of memory die 200, including the system control logic 212, can be formed as part of a single die. In other embodiments, some or all of system control logic 212 can be formed on a different die.

In one embodiment, memory array 202 includes a three-dimensional memory array of non-volatile memory cells in which multiple memory levels are formed above a single substrate, such as a wafer. The memory array may be any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory array 202 is a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory array 202 is not limited to the examples above. Many different types of memory array architectures or memory technologies can be used to form memory array 202. No particular non-volatile memory technology is required for purposes of the new claimed embodiments proposed herein.

Other examples of suitable technologies for memory cells of the memory array 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory array 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte.

In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells.

In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe—Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light.

In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory array, memory construction or material composition, but covers many relevant memory arrays within the spirit and scope of the technology as described herein and as understood by one of ordinary skill in the art.

The elements of FIG. 2A can be grouped into two parts: (1) memory array 202 and (2) peripheral circuitry, which includes all of the other components depicted in FIG. 2A. An important characteristic of a memory circuit is its capacity, which can be increased by increasing the area of the memory die of storage system 100 that is given over to the memory array 202. However, this reduces the area of the memory die available for the peripheral circuitry. This can place quite severe restrictions on these elements of the peripheral circuitry.

For example, the need to fit sense blocks within the available area can be a significant restriction on sense amplifier design architectures. With respect to the system control logic 212, reduced availability of area can limit the available functionalities that can be implemented on-chip. Consequently, a basic trade-off in the design of a memory die for storage system 100 is the amount of area to devote to memory array 202 and the amount of area to devote to the peripheral circuitry.

Another area in which memory array 202 and the peripheral circuitry are often at odds is in the processing involved in forming these regions, since these regions often involve differing processing technologies and the trade-off in having differing technologies on a single die.

For example, when memory array 202 is NAND flash, this is an NMOS structure, while the peripheral circuitry is often CMOS based. For example, elements such as sense amplifier circuits, charge pumps, logic elements in a state machine, and other peripheral circuitry in system control logic 212 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed die that are subsequently bonded together. More specifically, memory array 202 can be formed on one die (referred to as the memory die) and some or all of the peripheral circuitry elements, including one or more control circuits, can be formed on a separate die (referred to as the control die).

For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology.

For example, a NAND memory die can be optimized for an NMOS based memory array structure, without regard to the CMOS elements that are implemented in a control die that can be optimized for CMOS processing. This allows more space for the peripheral elements, which can now incorporate additional capabilities that could not readily be incorporated were they restricted to the margins of the same die with the memory cell array.

The two separate die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of an embodiment of an integrated memory assembly 236. One or more integrated memory assemblies 236 may be used to implement non-volatile memory 106 of storage system 100.

Integrated memory assembly 236 includes two types of semiconductor die (or more succinctly, “die”). Memory die 238 includes memory array 202, which includes non-volatile memory cells. Control die 240 includes row control circuitry 204, column control circuitry 208 and system control logic 212 (as described above). In some embodiments, control die 240 is configured to connect to memory array 202 in memory die 238. In some embodiments, memory die 238 and control die 240 are bonded together.

FIG. 2B shows an example of the peripheral circuitry, including control circuits, formed in a peripheral circuit or control die 240 coupled to memory array 202 formed in memory die 238. Common components are labelled similarly to FIG. 2A. System control logic 212, row control circuitry 204, and column control circuitry 208 are located in control die 240. In some embodiments, all or a portion of column control circuitry 208 and all or a portion of row control circuitry 204 are located on memory die 238. In some embodiments, some of the circuitry in system control logic 212 is located on the on memory die 238.

System control logic 212, row control circuitry 204, and column control circuitry 208 may be formed by a common process (e.g., a CMOS process), so that adding elements and functionalities, such as ECC, more typically found on memory controller 104 may require few or no additional process steps (i.e., the same process steps used to fabricate controller 104 also may be used to fabricate system control logic 212, row control circuitry 204, and column control circuitry 208). Control die 240 also could be referred to as a CMOS die, due to the use of CMOS technology to implement some or all of row control circuitry 204, column control circuitry 208 and system control logic 212.

FIG. 2B shows column control circuitry 208 including sense blocks 220 (e.g., sense blocks 220a, 220b, . . . , 220p) on control die 240 coupled to memory array 202 on the memory die 238 through electrical paths 210. For example, electrical paths 210 may provide electrical connection between column decoder 222, driver circuitry 224, and block select 226 and bit lines of memory array 202.

Electrical paths 210 may extend from column control circuitry 208 in control die 240 through pads on control die 240 that are bonded to corresponding pads of memory die 238. Each bit line of memory array 202 may have a corresponding electrical path in electrical paths 210, including a pair of bond pads, which connects to column control circuitry 208.

Similarly, row control circuitry 204, including row decoder 214, array drivers 216, and block select 218 are coupled to memory array 202 through electrical paths 206. Each of electrical path 206 may correspond to a word line, dummy word line, or select gate line. Additional electrical paths also may be provided between control die 240 and memory die 238.

For purposes of this document, the phrase “one or more control circuits” can include any one of or any combination of memory controller 104, state machine 228, all or a portion of system control logic 212, all or a portion of row control circuitry 204, all or a portion of column control circuitry 208, a microcontroller, a microprocessor, and/or other similar functioned circuits.

The one or more control circuits can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

In some embodiments, integrated memory assembly 236 may include more than one control die 240 and more than one memory die 238. In some embodiments, integrated memory assembly 236 includes a stack of multiple control die 240 and multiple memory die 238.

FIG. 2C depicts a side view of an embodiment of an integrated memory assembly 236 stacked on a substrate 242 (e.g., a stack that includes multiple control die 240 and multiple memory die 238). In the example depicted in FIG. 2C, integrated memory assembly 236 has three control die 240 and three memory die 238. In some embodiments, there are more than three memory die 238and more than three control die 240.

Each control die 240 is affixed (e.g., bonded) to at least one memory die 238 via bond pads 244/246 are depicted. There may be many more bond pads. A space between die 238, 240 that are bonded together is filled with a solid layer 248, which may be formed from epoxy or other resin or polymer. This solid layer 248 protects the electrical connections between the die 238, 240, and further secures the die together.

Integrated memory assembly 236 may for example be stacked with a stepped offset, leaving the bond pads at each level uncovered and accessible from above. Wire bonds 250 connected to the bond pads connect the control die 240 to substrate 242. A number of such wire bonds may be formed across the width of each control die 240 (i.e., into the page of FIG. 2C).

A memory die through silicon via (TSV) 252 may be used to route signals through a memory die 238. A control die TSV 254 may be used to route signals through a control die 240. TSVs 252, 254 may be formed before, during or after formation of the integrated circuits in semiconductor die 238, 240. The TSVs may be formed by etching holes through the wafers.

Solder balls 256 optionally may be affixed to contact pads 258 on a lower surface of substrate 242. Solder balls 256 may be used to couple integrated memory assembly 236 electrically and mechanically to a host device such as a printed circuit board. Solder balls 256 may form a part of the interface between integrated memory assembly 236 and memory controller 104.

FIG. 2D depicts a side view of another embodiment of integrated memory assembly 236 stacked on substrate 242. Integrated memory assembly 236 of FIG. 2D has three control die 240 and three memory die 238. In some embodiments, there are many more than three memory die 238 and many more than three control die 240. In this example, each control die 240 is bonded to at least one memory die 238. Optionally, a control die 240 may be bonded to two or more memory die 238.

Some bond pads 244, 246 are depicted. There may be many more bond pads. A space between two dies 238, 240 that are bonded together is filled with a solid layer 248, which may be formed from epoxy or other resin or polymer. In contrast to the example in FIG. 2C, integrated memory assembly 236 in FIG. 2D does not have a stepped offset. A memory die TSV 252 may be used to route signals through a memory die 238. A control die TSV 254 may be used to route signals through a control die 240.

Solder balls 256 optionally may be affixed to contact pads 258 on a lower surface of substrate 242. Solder balls 256 may be used to couple integrated memory assembly 236 electrically and mechanically to a host device such as a printed circuit board. Solder balls 256 may be omitted where the integrated memory assembly 236 is to be used as an LGA package.

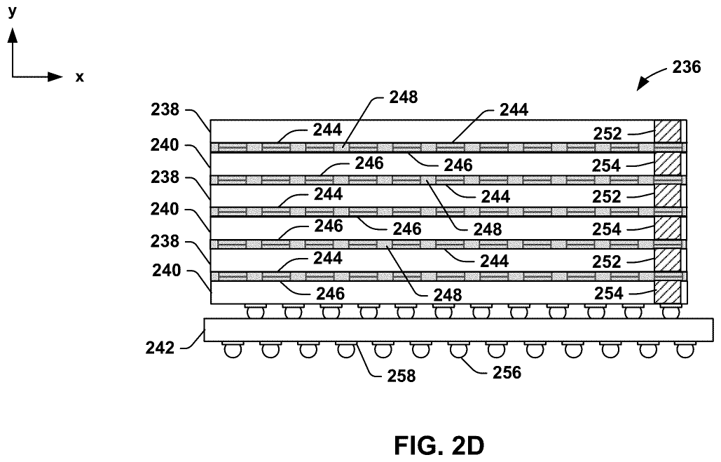

FIG. 3 is a perspective view of a portion of an example embodiment of a monolithic three dimensional memory array/structure that can include memory array 202, which includes a plurality non-volatile memory cells arranged as vertical NAND strings. For example, FIG. 3 shows a portion of one block of memory. The structure depicted includes a set of bit lines BL positioned above a stack of alternating dielectric layers and conductive layers. For example purposes, one of the dielectric layers is marked as D and one of the conductive layers (also called word line layers) is marked as W.

The number of alternating dielectric layers and conductive layers can vary based on specific implementation requirements. One set of embodiments includes between 108-300 alternating dielectric layers and conductive layers. More or less than 108-300 layers can also be used. As will be explained below, the alternating dielectric layers and conductive layers are divided into four or more regions (e.g., sub-blocks) by local interconnects LI. FIG. 3 shows two fingers and two local interconnects LI.

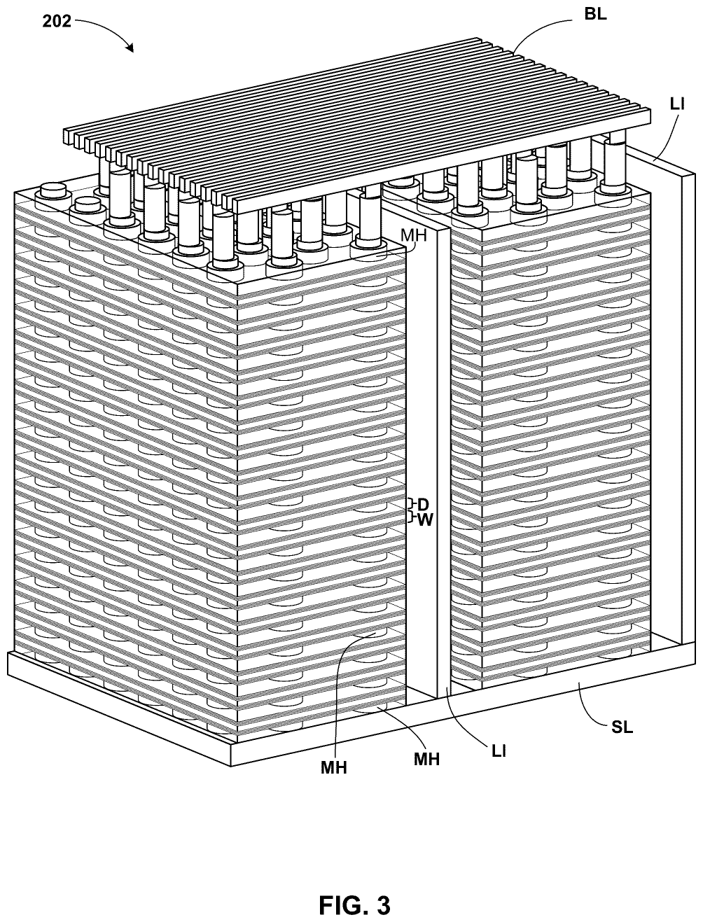

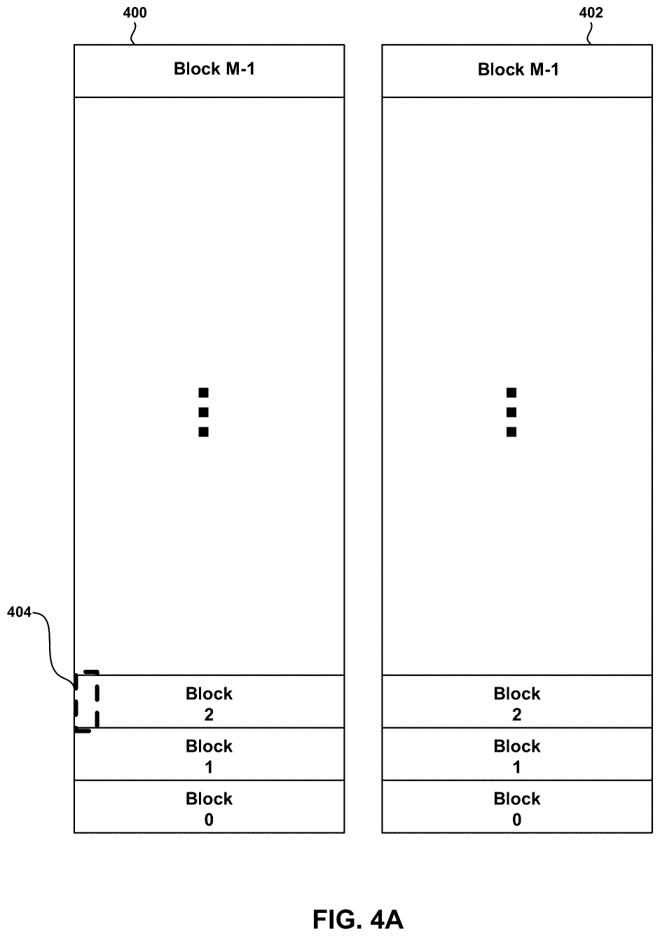

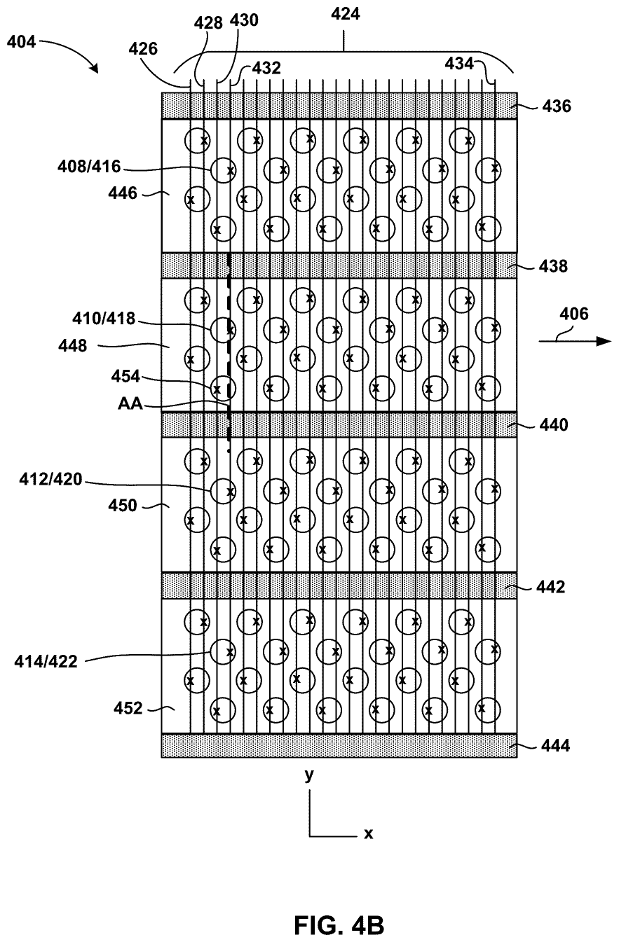

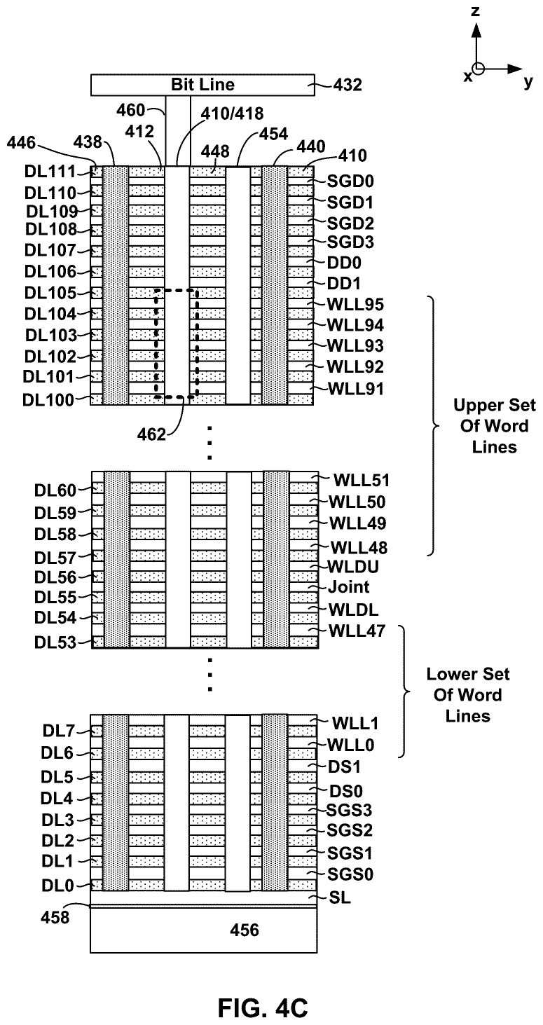

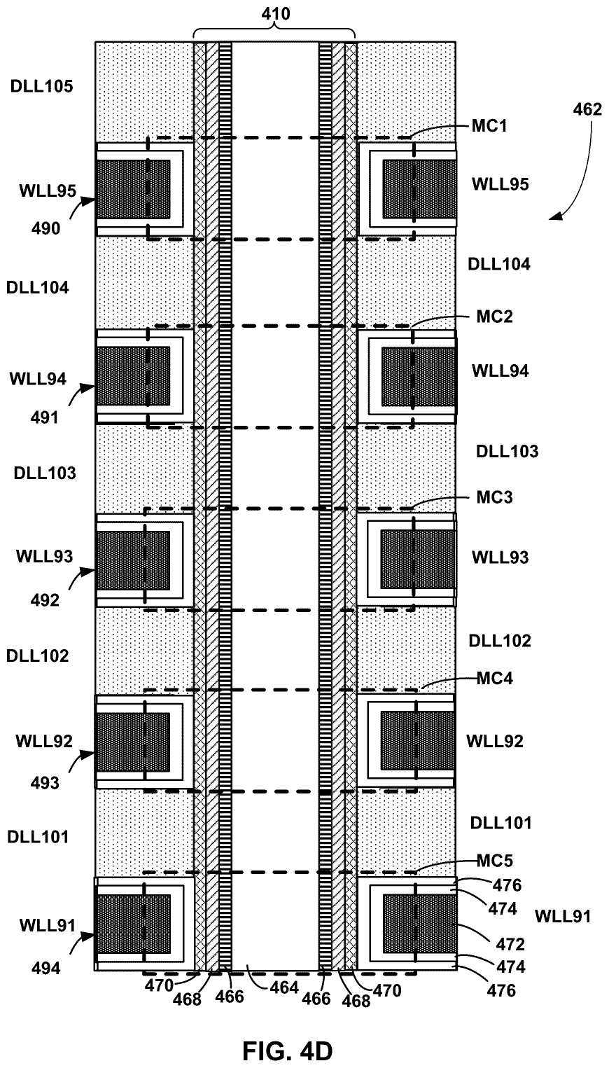

Below the alternating dielectric layers and word line layers is a source line layer SL. Memory holes are formed in the stack of alternating dielectric layers and conductive layers. For example, one of the memory holes is marked as MH. In an embodiment, NAND strings are formed by filling the memory hole with materials including a charge-trapping material to create a vertical column of memory cells. Each memory cell can store one or more bits of data. More details of the three dimensional monolithic memory array that comprises memory array 202 is provided below with respect to FIG. 4A-4E.

FIG. 4A is a block diagram depicting an example organization of memory array 202, which is divided into two planes 400 and 402. Each plane is then divided into M blocks. In one example, each plane has about 2000 blocks. However, different numbers of blocks and planes also can be used. In an embodiment, a block of memory cells is a unit of erase. That is, all memory cells of a block are erased together.

In some embodiments, a block represents a group of connected memory cells as the memory cells of a block share a common set of word lines. For example, the word lines for a block are all connected to all of the vertical NAND strings for that block. Although FIG. 4A shows two planes 400/402, more or less than two planes can be implemented. In some embodiments, memory array 202 includes eight planes.

FIGS. 4B-4E depict an example three dimensional (“3D”) NAND structure that corresponds to the structure of FIG. 3 and can be used to implement memory array 202 of FIGS. 2A and 2B. FIG. 4B is a block diagram depicting a top view of a portion of one block from memory array 202. The portion of the block depicted in FIG. 4B corresponds to portion 404 in block 2 of FIG. 4A. As can be seen from FIG. 4B, the block depicted in FIG. 4B extends in the direction 406. In an embodiment, memory array 202 has many layers, although FIG. 4B depicts only the top layer.

FIG. 4B depicts a plurality of circles that represent vertical columns. Each vertical column includes multiple select transistors (also referred to as a select gate or selection gate) and multiple memory cells. In an embodiment, each vertical column implements a NAND string.

For example, FIG. 4B depicts vertical columns 408, 410, 412 and 414. Vertical column 408 implements NAND string 416. Vertical column 410 implements NAND string 418. Vertical column 412 implements NAND string 420. Vertical column 414 implements NAND string 422. More details of the vertical columns are provided below. Because the block depicted in FIG. 4B extends in the direction of arrow 406, the block includes more vertical columns than depicted in FIG. 4B

FIG. 4B also depicts a set of bit lines 424, including bit lines 426, 428, 430, 432, . . . 434. FIG. 4B shows twenty four bit lines because only a portion of the block is depicted. It is contemplated that more than twenty four bit lines connected to vertical columns of the block. Each of the circles representing vertical columns has an “x” to indicate its connection to one bit line. For example, bit line 432 is connected to vertical columns 408, 410, 412 and 414.

The block depicted in FIG. 4B includes a set of local interconnects 436, 438, 440, 442 and 444 that connect the various layers to a source line below the vertical columns. Local interconnects 436, 438, 440, 442 and 444 also serve to divide each layer of the block into four regions; for example, the top layer depicted in FIG. 4B is divided into regions 446, 448, 450 and 452, which are referred to as fingers. In the layers of the block that implement memory cells, the four regions are referred to as word line fingers that are separated by the local interconnects.

In an embodiment, word line fingers on a common level of a block connect together to form a single word line. In another embodiment, word line fingers on the same level are not connected together. In an example implementation, a bit line only connects to one vertical column in each of regions 446, 448, 450 and 452. In that implementation, each block has sixteen rows of active columns and each bit line connects to four rows in each block.

In an embodiment, all four rows connected to a common bit line are connected to the same word line (via different word line fingers on the same level that are connected together). Therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts a portion of an embodiment of a three dimensional memory array 202 showing a cross-sectional view along line AA of FIG. 4B. This cross sectional view cuts through vertical columns 410 and 454 and region 448 (see FIG. 4B). The structure of FIG. 4C includes four drain side select layers SGD0, SGD1, SGD2 and SGD3, four source side select layers SGS0, SGS1, SGS2 and SGS3, six dummy word line layers DD0, DD1, DS0, DS1, WLDL, WLDU, and ninety six data word line layers WLL0-WLL95 for connecting to data memory cells. Other embodiments can implement more or less than four drain side select layers, more or less than four source side select layers, more or less than six dummy word line layers, and more or less than ninety six word lines.

Vertical columns 410 and 454 are depicted protruding through the drain side select layers, source side select layers, dummy word line layers and word line layers. In one embodiment, each vertical column comprises a vertical NAND string.

For example, vertical column 410 comprises NAND string 418. Below the vertical columns and the layers listed below is substrate 456, an insulating film 458 on the substrate, and source line SL. The NAND string of vertical column 410 has a source end at a bottom of the stack and a drain end at a top of the stack. As in agreement with FIG. 4B, FIG. 4C shows vertical column 410 connected to Bit Line 432 via connector 460. Local interconnects 438 and 440 also are depicted.

For ease of reference, drain side select layers SGD0, SGD1, SGD2 and SGD3, source side select layers SGS0, SGS1, SGS2 and SGS3, dummy word line layers DD0, DD1. DS0, DS1, WLDL and WLDU, and data word line layers WLL0-WLL95 collectively are referred to as the conductive layers. Between conductive layers are dielectric layers DL0-DL111. For example, dielectric layers DL104 is above word line layer WLL94 and below word line layer WLL95. In an embodiment, the dielectric layers are made from SiO₂. In other embodiments, other dielectric materials can be used to form the dielectric layers.

In an embodiment, drain side select layers SGD0, SGD1, SGD2 and SGD3 drain side selection lines, source side select layers SGS0, SGS1, SGS2 and SGS3 implement source side selection lines; dummy word line layers DD0, DD1, DS0, DS1, WLDL and WLDU implement dummy word lines, and data word line layers WLL0-WLL95 implement data word lines. In one embodiment, data word lines, dummy word lines, drain side selection lines and source side selection lines are all referred to generically as word lines.

The non-volatile memory cells are formed along vertical columns which extend through alternating conductive and dielectric layers in the stack. In one embodiment, the memory cells are arranged in NAND strings. The word line layers WLL0-WLL95 connect to memory cells (also called data memory cells). Dummy word line layers DD0, DD1, DS0, DS1. WLDL and WLDU connect to dummy memory cells.

A dummy memory cell does not store and is not eligible to store host data (data provided from the host, such as data from a user of the host), while a data memory cell is eligible to store host data. In some embodiments, data memory cells and dummy memory cells may have a same structure. A dummy word line is connected to dummy memory cells. Drain side select layers SGD0, SGD1, SGD2 and SGD3 are used to electrically connect and disconnect NAND strings from bit lines. Source side select layers SGS0, SGS1, SGS2 and SGS3 are used to electrically connect and disconnect NAND strings from the source line SL.

FIG. 4C also shows a Joint area. In one embodiment it is expensive and/or challenging to etch ninety six word line layers intermixed with dielectric layers. To ease this burden, one embodiment includes laying down a first stack of forty eight word line layers alternating with dielectric layers, laying down the Joint area, and laying down a second stack of forty eight word line layers alternating with dielectric layers. The Joint area is positioned between the first stack and the second stack. The Joint area is used to connect to the first stack to the second stack.

In FIG. 4C, the first stack is labeled as the “Lower Set of Word Lines” and the second stack is labeled as the “Upper Set of Word Lines.” In one embodiment, the Joint area is made from the same materials as the word line layers. In one example set of implementations, the plurality of word lines (word lines are one example of control lines, bit lines can also be considered control lines) comprises a first stack of alternating word line layers and dielectric layers, a second stack of alternating word line layers and dielectric layers, and a joint area between the first stack and the second stack, as depicted in FIG. 4C.

FIG. 4D depicts a cross sectional view of region 462 of FIG. 4C that includes a portion of vertical column 410 (a memory hole). In an embodiment, the vertical columns are round, but other shapes can be used. In one embodiment, vertical column 410 includes an inner core layer 464 that is made of a dielectric, such as SiO₂. Other materials also can be used. Surrounding inner core 464 is polysilicon channel 466. Materials other than polysilicon can also be used. Note that channel 466 connects to the bit line and the source line.

Surrounding channel 466 is a tunneling dielectric 468. In one embodiment, tunneling dielectric 468 has an ONO structure. Surrounding tunneling dielectric 468 is charge trapping layer 470, such as (for example) Silicon Nitride. Other memory materials and structures can also be used. The technology described herein is not limited to any particular material or structure.

FIG. 4D depicts dielectric layers DLL105, DLL104, DLL103, DLL102 and DLL101, as well as word line layers WLL95, WLL94, WLL93, WLL92, and WLL91. Each of the word line layers includes a word line region 472 surrounded by an aluminum oxide layer 474, which is surrounded by a blocking oxide layer 476. In other embodiments, blocking oxide layer 476 can be a vertical layer parallel and adjacent to charge trapping layer 470. The physical interaction of the word line layers with the vertical column forms the memory cells. Thus, a memory cell, in one embodiment, includes channel 466, tunneling dielectric 468, charge trapping layer 470, blocking oxide layer 476, aluminum oxide layer 474 and word line region 472.

For example, word line layer WLL95 and a portion of vertical column 410 comprise a memory cell MC1. Word line layer WLL94 and a portion of vertical column 410 comprise a memory cell MC2. Word line layer WLL93 and a portion of vertical column 410 comprise a memory cell MC3. Word line layer WLL92 and a portion of vertical column 410 comprise a memory cell MC4. Word line layer WLL91 and a portion of vertical column 410 comprise a memory cell MC5. In other architectures, a memory cell may have a different structure; however, the memory cell would still be the storage unit.

When a memory cell is programmed, electrons are stored in a portion of the charge trapping layer 470 which is associated with the memory cell. These electrons are drawn into the charge trapping layer 470 from channel 466, through tunneling dielectric 468, in response to an appropriate voltage on word line region 472. The threshold voltage (Vth) of a memory cell is increased in proportion to the amount of stored charge.

In one embodiment, programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as gate induced drain leakage (GIDL).

FIG. 4E is a schematic diagram of a portion of the memory depicted in in FIGS. 3-4D. FIG. 4E shows physical data word lines WLL0-WLL95 running across the entire block. The structure of FIG. 4E corresponds to portion 404 in Block 2 of FIGS. 4A-D, including bit lines 426, 428, 430, 432, . . . 434. Within the block, each bit line is connected to four NAND strings.

Drain side selection lines SGD0, SGD1, SGD2 and SGD3 are used to determine which of the four NAND strings connect to the associated bit line(s). Source side selection lines SGS0, SGS1, SGS2 and SGS3 are used to determine which of the four NAND strings connect to the common source line.

The block also can be thought of as divided into four sub-blocks SB0, SB1, SB2 and SB3. Sub-block SB0 corresponds to those vertical NAND strings controlled by SGD0 and SGS0, sub-block SB1 corresponds to those vertical NAND strings controlled by SGD1 and SGS1, sub-block SB2 corresponds to those vertical NAND strings controlled by SGD2 and SGS2, and sub-block SB3 corresponds to those vertical NAND strings controlled by SGD3 and SGS3.

Although the example memory system of FIGS. 3-4E is a three dimensional memory array that includes vertical NAND strings with charge-trapping material, other (2D and 3D) memory arrays can also be used with the technology described herein.

The memory systems discussed above can be erased, programmed and read. At the end of a successful programming process (with verification), the threshold voltages of the memory cells should be within one or more distributions of threshold voltages for programmed memory cells or within a distribution of threshold voltages for erased memory cells, as appropriate.

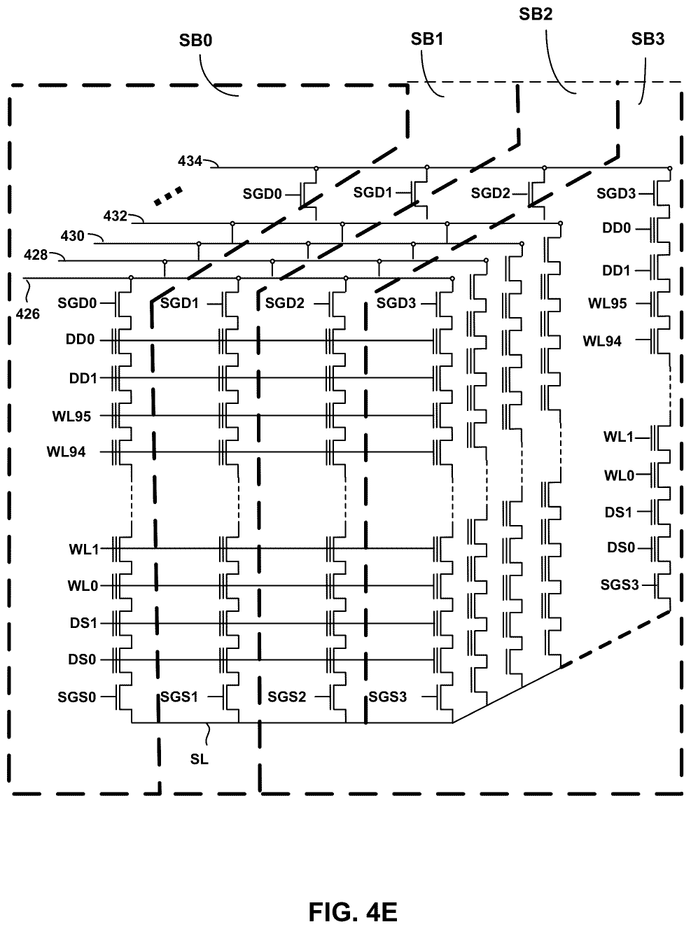

FIG. 5 is a graph of threshold voltage versus number of memory cells, and illustrates example threshold voltage distributions for the memory array when each memory cell stores three bits of data. Other embodiments, however, may use other data capacities per memory cell (e.g., such as one, two, four, or five bits of data per memory cell).

FIG. 5 shows eight threshold voltage distributions, corresponding to eight data states. For a data state N, that data state N has higher threshold voltages than data state N−1 and lower threshold voltages than data state N+1. The first threshold voltage distribution (data state) S0 represents memory cells that are erased. The other seven threshold voltage distributions (data states) S1-S7 represent memory cells that are programmed and, therefore, are also called programmed states or programmed data states. In some embodiments, data states S1-S7 can overlap, with memory controller 104 relying on error correction to identify the correct data being stored.

FIG. 5 shows seven read reference voltages, Vr1, Vr2, Vr3, Vr4, Vr5, Vr6, and Vr7 for reading data from memory cells. By testing (e.g., performing sense operations) whether the threshold voltage of a given memory cell is above or below the seven read reference voltages, the system can determine what data state (i.e., S0, S1, S2, S3, . . . ) a memory cell is in.

FIG. 5 also shows seven verify reference voltages, Vv1, Vv2, Vv3, Vv4, Vv5, Vv6, and Vv7 (also referred to as verify target voltages). When programming memory cells to data states S1, S2, S3, S4, S5, S6 and S7, the system will test whether the memory cells have threshold voltages greater than or equal to Vv1, Vv2, Vv3, Vv4, Vv5, Vv6, and Vv7, respectively.

In an embodiment, known as full sequence programming, memory cells can be programmed from the erased data state S0 directly to any of the programmed data states S1-S7. For example, a population of memory cells to be programmed may first be erased so that all memory cells in the population are in erased data state S0. Then, a programming process is used to program memory cells directly into data states S1, S2, S3, S4, S5, S6, and/or S7.

For example, while some memory cells are being programmed from data state S0 to data state S1, other memory cells are being programmed from data state S0 to data state S2 and/or from data state S0 to data state S3, and so on. The arrows of FIG. 5 represent the full sequence programming. The technology described herein can also be used with other types of programming in addition to full sequence programming including (but not limited to) multiple stage/phase programming.

Each threshold voltage distribution (data state) of FIG. 5 corresponds to predetermined values for the set of data bits stored in the memory cells. The specific relationship between the data programmed into the memory cell and the threshold voltage levels of the memory cell depends upon the data encoding scheme adopted for the memory cells. In an embodiment, data values are assigned to the threshold voltage ranges using a Gray code assignment so that if the threshold voltage of a memory erroneously shifts to its neighboring physical state, only one bit will be affected.

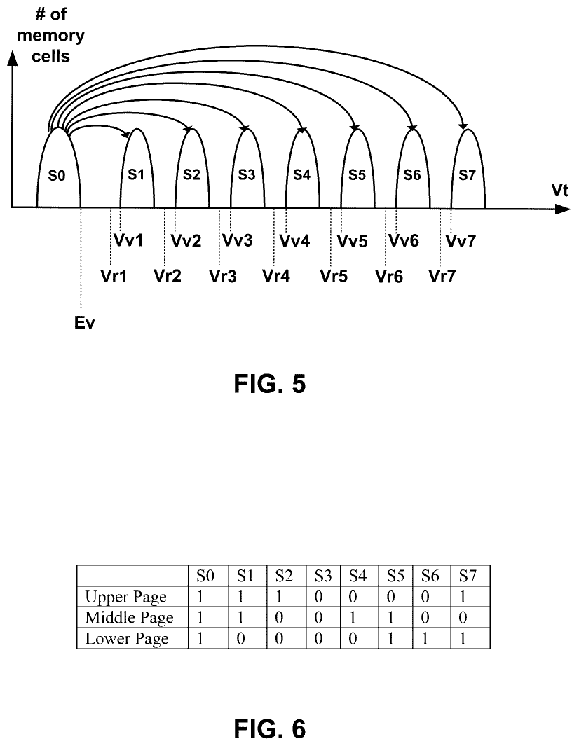

FIG. 6 is a table describing an example assignment of data values to data states. In the table of FIG. 6, S0=111 (erased state), S1=110, S2=100, S3=000, S4=010, S5=011, S6=001 and S7=101. Other encodings of data also can be used. No particular data encoding is required by the technology disclosed herein. In an embodiment, when a block is subjected to an erase operation, all memory cells are moved to data state S0, the erased state.

In general, during verify operations and read operations, the selected word line is connected to a voltage (one example of a reference signal), a level of which is specified for each read operation (e.g., see read reference voltages Vr1, Vr2, Vr3, Vr4, Vr5, Vr6, and Vr7, of FIG. 5) or verify operation (e.g., see verify reference voltages Ev. Vv1, Vv2, Vv3, Vv4, Vv5, Vv6, and Vv7 of FIG. 5) to determine whether a threshold voltage of the concerned memory cell has reached such level.

After applying the word line voltage, the conduction current of the memory cell is measured to determine whether the memory cell turned on (conducted current) in response to the voltage applied to the word line. If the conduction current is measured to be greater than a certain value, then it is assumed that the memory cell turned on and the voltage applied to the word line is greater than the threshold voltage of the memory cell. If the conduction current is not measured to be greater than the certain value, then it is assumed that the memory cell did not turn on and the voltage applied to the word line is not greater than the threshold voltage of the memory cell.

During a read or verify process, the unselected memory cells are provided with one or more read pass voltages (also referred to as bypass voltages) at their control gates so that these memory cells will operate as pass gates (e.g., conducting current regardless of whether they are programmed or erased).

There are many ways to measure the conduction current of a memory cell during a read or verify operation. In one example, the conduction current of a memory cell is measured by the rate it discharges or charges a dedicated capacitor in the sense amplifier. In another example, the conduction current of the selected memory cell allows (or fails to allow) the NAND string that includes the memory cell to discharge a corresponding bit line. The voltage on the bit line is measured after a period of time to see whether it has been discharged or not. Note that the technology described herein can be used with different methods known in the art for verifying/reading. Other read and verify techniques known in the art can also be used.

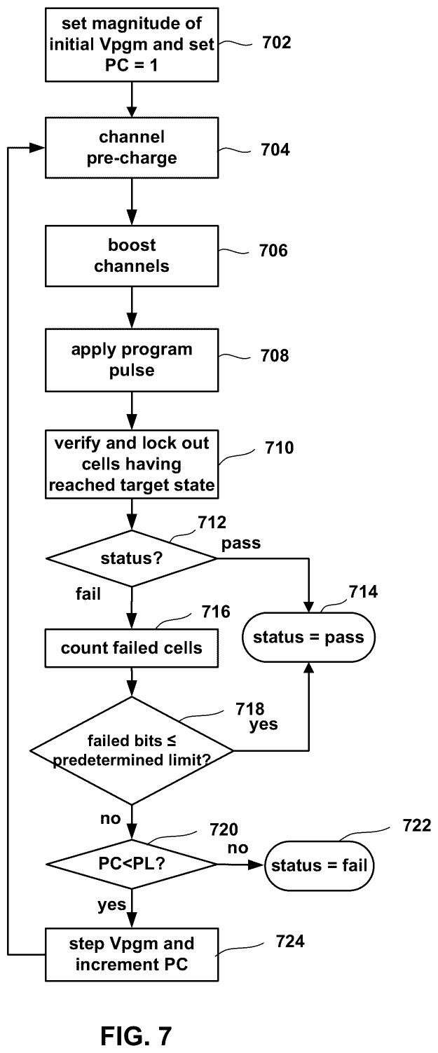

FIG. 7 is a flowchart describing an embodiment of a process for programming that is performed by memory die 200 and/or integrated assembly 236. In one example embodiment, the process of FIG. 7 is performed on memory die 200 using the one or more control circuits (e.g., system control logic 212, column control circuitry 208, row control circuitry 204) discussed above.

In an example embodiment, the process of FIG. 7 is performed by integrated memory assembly 236 using the one or more control circuits (e.g., system control logic 212, column control circuitry 208, row control circuitry 204) of control die 240 to program memory cells on memory die 238. The process includes multiple loops, each of which includes a program phase and a verify phase.

The process of FIG. 7 is performed to implement the full sequence programming, as well as other programming schemes including multi-stage programming. When implementing multi-stage programming, the process of FIG. 7 is used to implement any/each stage of the multi-stage programming process.

Typically, the program voltage applied to the control gates (via a selected data word line) during a program operation is applied as a series of program pulses (e.g., voltage pulses). Between programming pulses are a set of verify pulses (e.g., voltage pulses) to perform verification. In many implementations, the magnitude of the program pulses is increased with each successive pulse by a predetermined step size.

In step 918 of FIG. 7, the program voltage (Vpgm) is initialized to the starting magnitude (e.g., ˜12-20V or another suitable level) and a program counter PC maintained by state machine 228 is initialized at 1.

In an embodiment, the set of memory cells selected to be programmed (referred to herein as the selected memory cells) are programmed concurrently and are all connected to the same data word line (the selected word line). There will likely be other memory cells that are not selected for programming (unselected memory cells) that are also connected to the selected word line.

That is, the selected word line will also be connected to memory cells that are supposed to be inhibited from programming. Additionally, as memory cells reach their intended target data state, they will be inhibited from further programming. Those NAND strings (e.g., unselected NAND strings) that include memory cells connected to the selected word line that are to be inhibited from programming have their channels boosted to inhibit programming.

When a channel has a boosted voltage, the voltage differential between the channel and the word line is not large enough to cause programming. To assist in the boosting, in step 704 the storage system will pre-charge channels of NAND strings that include memory cells connected to the selected word line that are to be inhibited from programming.

In step 706, NAND strings that include memory cells connected to the selected word line that are to be inhibited from programming have their channels boosted to inhibit programming. Such NAND strings are referred to herein as “unselected NAND strings.” In one embodiment, the unselected data word lines receive one or more boosting voltages (e.g., ˜7-11 volts) to perform boosting schemes. A program inhibit voltage is applied to the bit lines coupled the unselected NAND string.

In step 708, a program pulse (e.g., voltage pulse) of the program signal Vpgm is applied to the selected word line (the data word line selected for programming). If a memory cell on a NAND string should be programmed, then the corresponding bit line is biased at a program enable voltage, in one embodiment. Herein, such a NAND string is referred to as a “selected NAND string.”

In step 708, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all the memory cells connected to the selected word line will concurrently have their Vt change, unless they are inhibited from programming.

In step 710, memory cells that have reached their target states are locked out from further programming. Step 710 may include performing verifying at one or more verify reference levels. In one embodiment, the verification process is performed by testing whether the threshold voltages of the memory cells selected for programming have reached the appropriate verify reference voltage.

In step 710, a memory cell may be locked out after the memory cell has been verified (by a test of the Vt) that the memory cell has reached its target state. If, in step 712, it is determined that all of the memory cells have reached their target threshold voltages (pass), the programming process is complete and successful because all selected memory cells were programmed and verified to their target states. A status of “PASS” is reported in step 714. Otherwise if, in step 712, it is determined that not all the memory cells have reached their target threshold voltages (fail), then the programming process continues to step 716.

In step 716, the system counts the number of memory cells that have not yet reached their respective target Vt distribution. That is, the system counts the number of memory cells that have, so far, failed to reach their target state. This counting can be done by the state machine 228, memory controller 104, or other logic. In one implementation, each of the sense blocks will store the status (pass/fail) of their respective cells. In one embodiment, there is one total count, which reflects the total number of memory cells currently being programmed that have failed the last verify step. In another embodiment, separate counts are kept for each data state.

In step 718, it is determined whether the count from step 716 is less than or equal to a predetermined limit. In one embodiment, the predetermined limit is the number of bits that can be corrected by ECC during a read process for a page (e.g., the unit of programming and the unit of reading) of memory cells. If the number of failed cells is less than or equal to the predetermined limit, than the programming process can stop and a status of “PASS” is reported in step 714. In this situation, enough memory cells programmed correctly such that the few remaining memory cells that have not been completely programmed can be corrected using ECC during the read process.

In some embodiments, the predetermined limit used in step 718 is below the number of bits that can be corrected by ECC during a read process to allow for future/additional errors. When programming less than all of the memory cells for a page, or comparing a count for only one data state (or less than all states), than the predetermined limit can be a pro-rata (or other) portion of the number of bits that can be corrected by ECC during a read process for the page of memory cells. In some embodiments, the limit is not predetermined. Instead, it changes based on the number of errors already counted for the page, the number of program-erase cycles performed or other criteria.

If the number of failed memory cells is not less than the predetermined limit, than the programming process continues at step 720 and the program counter PC is checked against the program limit value (PL). Examples of program limit values include 1, 12, 16, 20 and 30, although other values can be used. If the program counter PC is not less than the program limit value PL, then the program process is considered to have failed and a status of FAIL is reported in step 722.

If the program counter PC is less than the program limit value PL, then the process continues at step 724 during which time the Program Counter PC is incremented by 1 and the program voltage Vpgm is stepped up to the next magnitude. For example, the next pulse will have a magnitude greater than the previous pulse by a step size (e.g., a step size of 0.1-1.0 volts). After step 724, the process loops back to step 704 and another program pulse is applied to the selected word line so that another iteration (steps 704-724) of the programming process of FIG. 7 is performed.

In an embodiment, programming serves to raise the threshold voltage of the memory cells to one of the programmed data states S1-S7. Erasing serves to lower the threshold voltage of the memory cells to the Erase data state S0.

One technique to erase memory cells in some memory devices is to bias a p-well (or other types of) substrate to a high voltage to charge up a NAND channel. An erase enable voltage (e.g., a low voltage) is applied to control gates of memory cells while the NAND channel is at a high voltage to erase the non-volatile storage elements (memory cells). Herein, this is referred to as p-well erase.

Another approach to erasing memory cells is to generate GIDL current to charge up the NAND string channel. An erase enable voltage is applied to control gates of the memory cells, while maintaining the NAND string channel potential to erase the memory cells. Herein, this is referred to as GIDL erase. Both p-well erase and GIDL erase may be used to lower the threshold voltage (Vt) of memory cells.

In an embodiment, the GIDL current is generated by causing a drain-to-gate voltage at a select transistor (e.g., SGD and/or SGS). A transistor drain-to-gate voltage that generates a GIDL current is referred to herein as a GIDL voltage. The GIDL current may result when the select transistor drain voltage is significantly higher than the select transistor control gate voltage. GIDL current is a result of carrier generation, i.e., electron-hole pair generation due to band-to-band tunneling and/or trap-assisted generation.

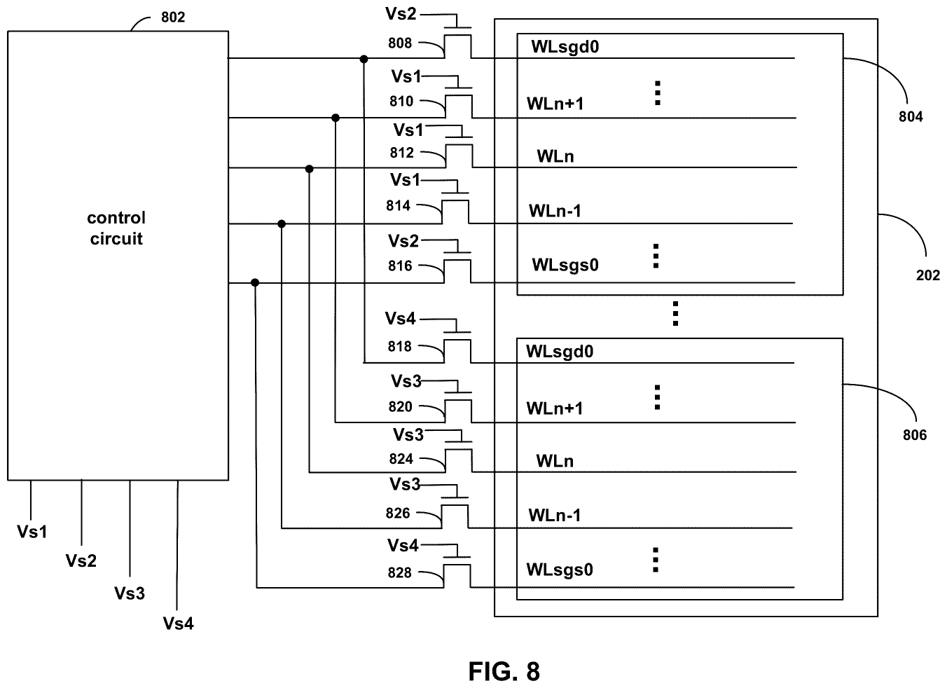

FIG. 8 depicts a schematic diagram of control circuit 802 connected to memory array 202. For memory array 202, FIG. 8 shows block 804 and block 806, although more than two blocks would be included in memory array 202. FIG. 8 only shows two blocks to make the drawing easier to read. Control circuit 802 can be any one or more of the control circuits discussed above. In one embodiment, a portion of control circuit 802 includes the row decoders discussed above.

FIG. 8 shows a plurality of word lines extending across the memory. For example, for both blocks 804 and 806, the word line depicted include WLsgs0, . . . , WLn−1, WLn, WLn+1, . . . , WLsgd0. The other word lines of the blocks are not explicitly depicted to make the drawing easier to read. In addition to row decoders, control circuit 802 includes one or more voltage sources that provide voltage signals which are transferred to the word lines via a plurality of word line switch transistors.

For block 804, FIG. 8 shows word lines switch transistor 808 connected to WLsgd0, word line switch transistor 810 connected to WLn+1, word line switch transistor 812 connected to WLn, word line switch transistor 814 connected to WLn 1 and word line switch transistor 816 connected to WLsgs0.

For block 806, FIG. 8 shows word line transistor 818 connected to WLsgd0, word line switch transistor 820 connected to WLn+1, word line switch transistor 824 connected to WLn, word line switch transistor 826 connected to WLn−1 and word line switch transistor 828 connected to WLsgs0.

Each of word line transistors 808-828 have their input terminal connected to control circuit 802 for receiving a voltage to be transferred to the respective word lines via the output terminals. Control circuit 802 provides various selection signals (one or more selection voltages or one or more deselect voltages) to the selection terminals of the word line switch transistor.

For example, signal Vs1 is provided to word line switches 810, 812 and 814, signal Vs2 is provided to word line switches 808 and 816, signal Vs3 is provided to the selection terminal of word line switches 820, 824 and 826, and signal Vs4 is provided to the selection terminals of word line switch transistors 818 and 828. In this manner, the word line switch transistors for a block can be turned ON or turned OFF so that the block is selected or not selected for a particular memory operation. In some embodiment Vs1=Vs2 and Vs3=Vs4.

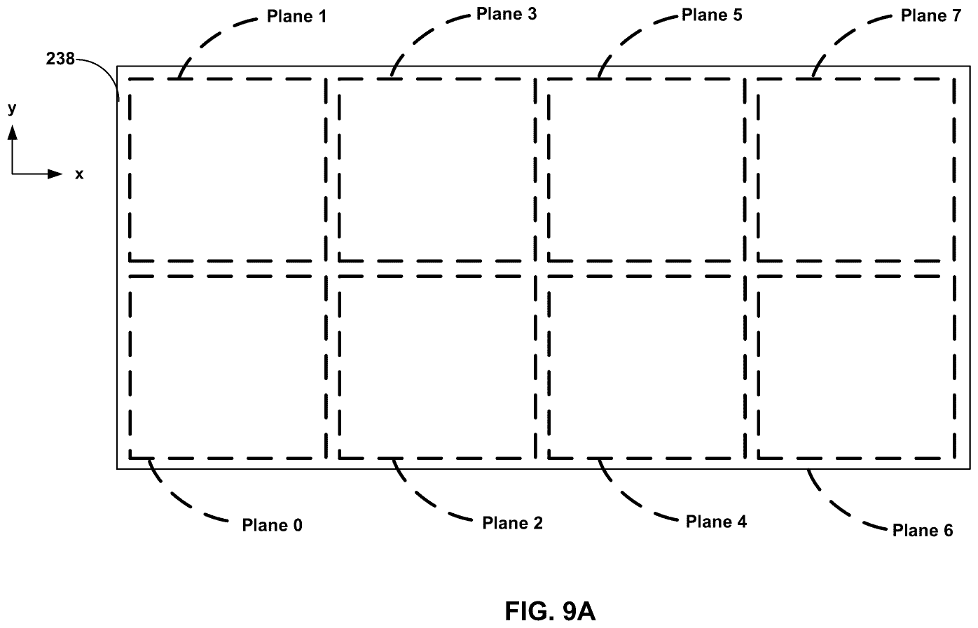

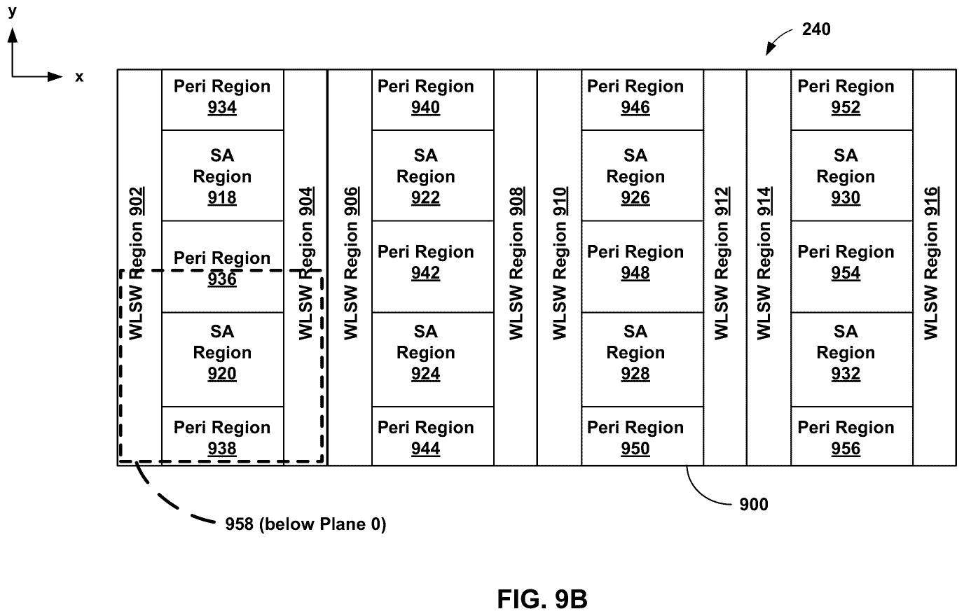

FIG. 9A depicts a top view of a memory die 238 that includes eight planes: Plane 0, Plane 1, Plane 2, Plane 3, Plane 4, Plane 5, Planer 6 and Plane 7. In other embodiments, more or less than eight planes can be implemented. In one example implementation, each plane includes a three dimensional non-volatile memory array (e.g., as described in FIGS. 4B-4E). Each of the three dimensional non-volatile memory arrays includes bit lines and word lines connected to non-volatile memory cells, as described above.

FIG. 9B depicts a top view of control die 240. Particularly, FIG. 9B is looking down on the top surface of substrate 900 of control die 240. The surface of substrate 900 is divided into various areas including a plurality of word line switch regions 902, 904, 906, 908, 910, 912, 914 and 916. Each of these word line switch regions includes a plurality of word line switches.

Control die 240 also includes a plurality of sense amp regions 918, 920, 922, 924, 926, 928, 930 and 932. Each of the sense amp regions includes sense blocks and supporting circuits.

Control die 240 further includes a plurality of peripheral circuit regions (also referred to as “Peri Regions”) 934, 936, 938, 940, 942, 944, 946, 948, 950, 952, 954 and 956. Each Peri Region includes various peripheral circuits (other than sense blocks and word line switch transistors) used to implement control die 240. For example, Peri Regions 934, 936, 938, 940, 942, 944, 946, 948, 950, 952, 954 and 956 could include the components of system control logic 212, components of row control circuitry 204, and/or the components of column control circuitry 208 (except for sense blocks 220) (see FIG. 2A and FIG. 2B).

In the embodiment of FIGS. 2B, 2C, and 2D, control die 240 of FIG. 9B is positioned below memory die 238. That is, the eight planes depicted in FIG. 9A would be positioned above the components depicted in FIG. 9B. Note that FIG. 9B includes a dashed line surrounding section 958 of control die 240 that is positioned below plane zero (see FIG. 9A). Section 958 includes word line switch regions 902 and 904, sense amp region 920, Peri Region 936, and Peri Region 938.

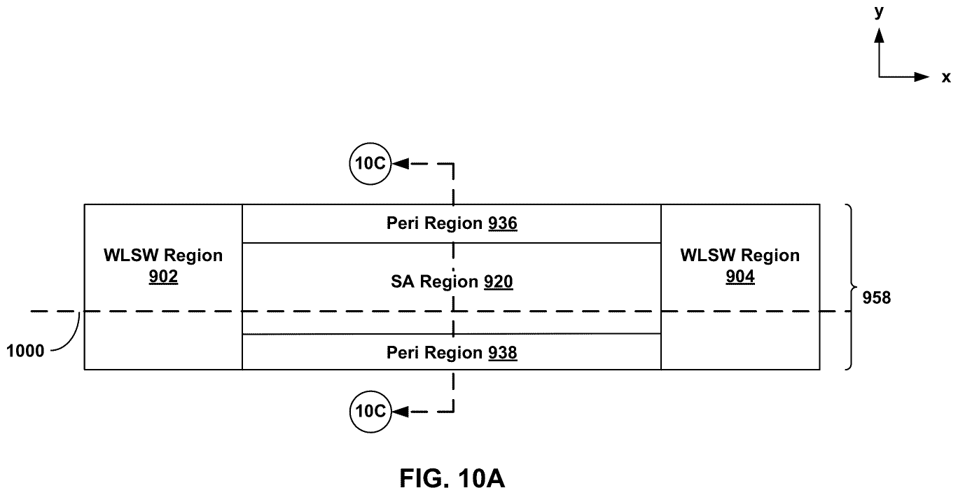

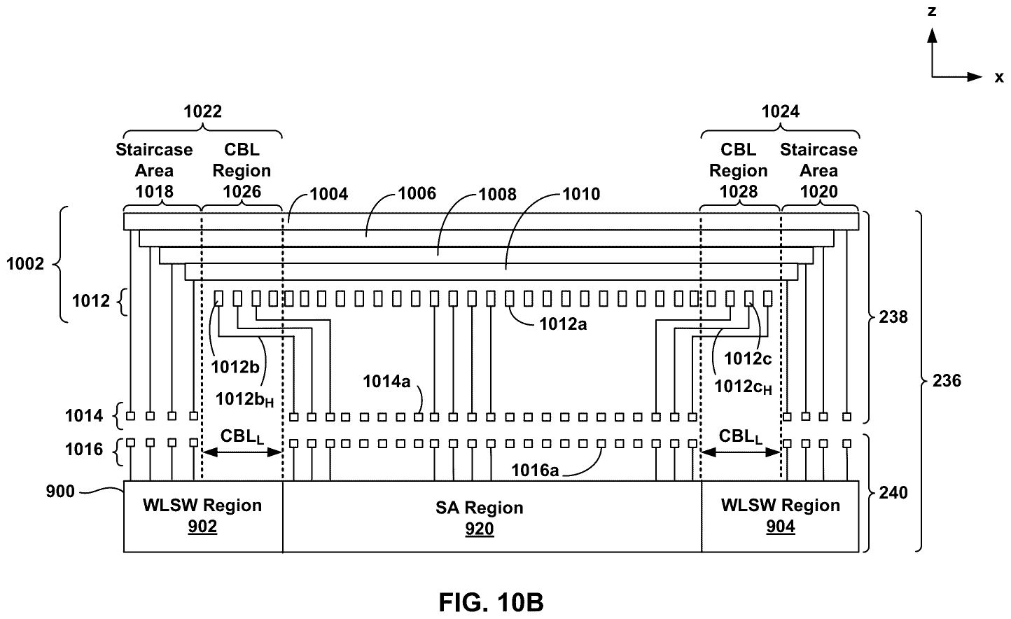

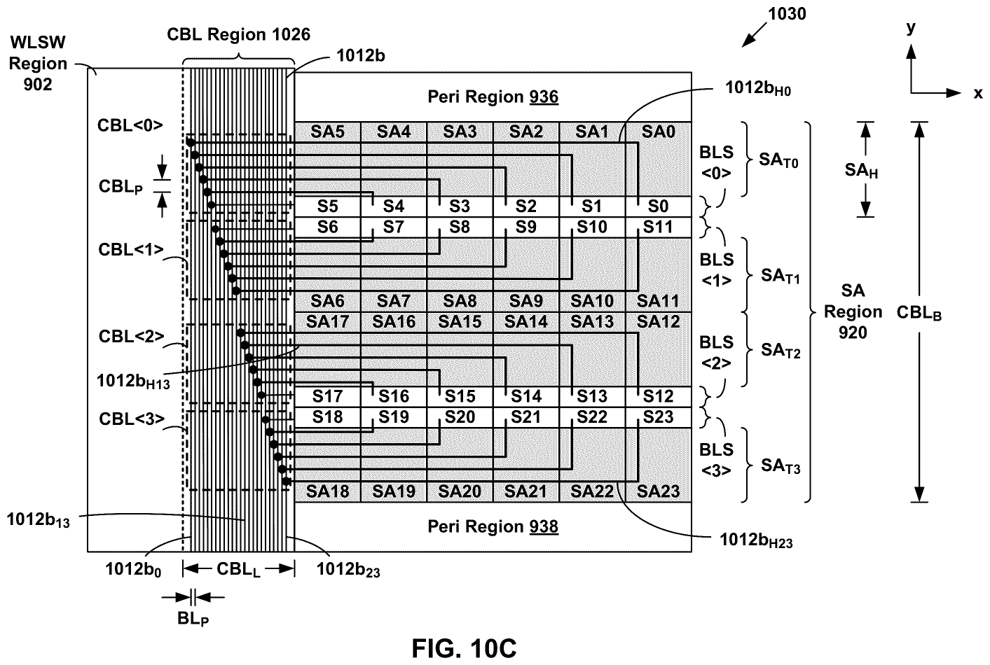

FIG. 10A shows a top view of section 958 of control die 240 and FIG. 10B shows a corresponding cross section of integrated assembly 236 (including a portion of memory die 238 and a portion of control die 240) along line 1000 of section 958. In FIG. 10B, the portion of control die 240 is the same portion 958 depicted in FIG. 10A and includes word line switch region 902, word line switch region 904 and sense amp region 920.

To facilitate an understanding of the relative orientation of memory die 238 and control die 240, x and y axes are depicted in FIG. 10A and x and z axes are depicted in FIG. 10B, with the top view of section 958 depicted in the x-y plane, and the cross-sectional view of integrated assembly 256 depicted in the x-z plane. In the following discussion of FIGS. 10A-10B, the term “horizontal” refers to a direction along the x-axis, and the term “vertical” will refer to a direction along the y-axis, and the term “elevation” will refer to a direction along the z-axis.

As depicted in FIG. 10B, memory die 238 is at an elevation above control die 240. Note that for purposes of this document, terms relating to orientation with respect to the integrated memory assembly 236 are relative to the semiconductor die. For example, regardless of whether integrated memory assembly 236 is in the orientation depicted in FIG. 10B, flipped vertically or rotated, memory die 238 is above control die 240.

The portion of memory die 238 depicted in FIG. 10B includes a non-volatile memory array 1002 forming plane zero, which includes a plurality of word lines 1004, 1006, 1008 and 1010. In an embodiment, word lines 1004, 1006, 1008 and 1010 are oriented horizontally. Only four word lines are depicted to make the drawing easier to read; however, in most embodiments more than four word lines would be implemented (as discussed above). To make the drawing easier to read, FIG. 10B does not show the dielectric regions between the word lines or the memory holes.

Below word lines 1004, 1006, 1008 and 1010 are a plurality of bit lines 1012 (e.g., one of the bit lines is labeled 1012a for example purposes). In an embodiment, bit lines 1012 are oriented vertically. Below bit lines 1012 are a set of bond pads 1014 for memory die 238 (e.g., one of the bond pads is labeled 1014a for example purposes).

Control die 240 includes substrate 900. The portion of substrate 900 depicted in FIG. 10B includes word line switch region 902, word line switch region 904, and sense amp region 920. Control die 240 also includes a plurality of bond pads 1016 (e.g., one of the bond pads is labeled 1016a for example purposes) that line up with bond pads 1014 to bond control die 240 to control die 238. That is, in one embodiment, each of bond pads 1014 is bonded to and aligned with a corresponding one of bond pads 1016.

As can be seen from FIG. 10B, word lines 1004, 1006, 1008, 1010 are arranged in an inverted staircase structure such that the word line length increases from bottom to top of the three dimensional non-volatile memory array. For example, the two ends of the stack of word lines 1004, 1006, 1008, 1010 are in the shape of an inverted staircase. This portion of where the staircases are positioned are referred to as “Staircase Areas,” which in FIG. 10B includes Staircase Area 1018 and Staircase Area 1020.

FIG. 10B shows how Staircase Areas 1018 and 1020 line up over word line switch regions 902 and 904, respectively. Staircase Areas 1018 and 1020 also can be referred to as word line hook up regions because control die 240 sends signals that connect to the word lines in these word line hook up regions/staircase areas 1018 and 1020.

As depicted in FIG. 10B, memory array 1002 is disposed above and includes end portions that extend beyond sense amp region 920. Conventionally, a memory array would have a same horizontal length as the underlying sense amp region. As a result, bit lines in the memory array would conventionally be routed in a direction parallel to the z-axis to the underlying sense amp region. In such a conventional scenario, word line switch regions would thus extend beyond the ends of the memory array, requiring a larger die size.

To reduce die size, memory array 1002 includes a first end portion 1022 and a second end portion 1024 that extend horizontally beyond the ends of sense amp region 920, such as shown in FIG. 10B. As a result, word line switch regions 902 and 904 may be located under first end portion 1022 and second end portion 1024, respectively, allowing the die size to be reduced.

In the example depicted in FIG. 10B, first end portion 1022 includes Staircase Area 1018, and second end portion 1024 includes Staircase Area 1020. In addition, first end portion 1022 includes a region 1026 in which bit lines 1012 (e.g., bit line 1012b) are disposed over word line switch region 902, and second end portion 1024 includes a region 1028 in which bit lines 1012 (e.g., bit line 1012c) are disposed over word line switch region 904.

Because bit lines 1012 in region 1026 and region 1028 are not disposed above sense amp region 920, portions of bit lines 1012 in region 1026 and region 1028 must be routed horizontally. For example, bit line 1012b includes a horizontally routed bit line portion 1012b_{H}, and bit line 1012c includes a horizontally routed bit line portion 1012C_{H}. The horizontally routed bit line portions 1012C_{H} are referred to herein as “cross bit lines,” region 1026 is also referred to herein as “cross bit line” (CBL) Region 1026, and region 1026 is also referred to herein as CBL Region 1028. Thus, first end portion 1022 includes Staircase Area 1018 and CBL Region 1026, and second end portion 1024 includes Staircase Area 1020 and CBL region 1028. In an embodiment, CBL region 1026 and CBL region 1028 have a same length CBL_{L}.

FIG. 10C shows a more detailed top view of a portion 1030 of section 958 of control die 240. In particular, FIG. 10C is a more detailed view of the layout of left portion of FIG. 10A. CBL Region 1026 has a length CBL_{L} and includes bit lines 1012b. In the illustrated example, CBL Region 1026 includes 24 bit lines 1012b₀ . . . 1012b₂₃, although CBL Region 1026 may include more or fewer than 24 bit lines 1012b. In an embodiment, bit lines 1012b in CBL Region 1026 are arranged vertically (i.e., parallel to the y-axis depicted in FIG. 10C).

In the example depicted in FIG. 10B, word line switch region 902 and Staircase Area 1018 and word line switch region 904 and Staircase Area 1020 are disposed at the edges of the plane. In an alternate embodiment, word line switch region 902 and Staircase Area 1018 and word line switch region 904 and Staircase Area 1020 may be disposed in the middle of the plane. In addition, as depicted in in FIG. 10B, CBL region 1026 is disposed above word line switch region 902 and CBL region 1028 is disposed above word line switch region 904. In other embodiments, CBL region 1026 and CBL region 1028 alternatively may be disposed above other circuitry, such as some other peripheral circuitry. In both alternative embodiments, CBL length CBLL may be defined as the length of the area that includes bit lines 1012 and extends beyond sense amp region 920. In addition, the technology described in this document and the formulas described below equally apply to such alternative embodiments.

In an embodiment, sense amp region 920 includes multiple sense amp tiers and multiple bit line switch regions. In the example depicted in FIG. 10C, sense amp region 920 includes a first number N1 of sense amp tiers SA_{T0}, SA_{T1}, SA_{T2} and SA_{T3}. In the embodiment of FIG. 10C. N1=4, although sense amp region 920 may include more or fewer than four sense amp tiers. In an embodiment, sense amp tiers SA_{T0}, SA_{T1}, SA_{T2} and SA_{T3} are arranged vertically (i.e., parallel to the y-axis depicted in FIG. 10C).

In the example depicted in FIG. 10C, sense amp region 920 includes a second number N2 of bit line switch regions BLS<0>, BLS<1>, BLS<2> and BLS<3>, and the first number N1 is equal to the second number N2 (e.g., N1=N2). In the embodiment of FIG. 10C, N1=N2=4, although sense amp region 920 may include more or fewer than four bit line switch regions. In an embodiment, bit line switch regions BLS<0>, BLS<1>, BLS<2> and BLS<3> also are arranged vertically (i.e., parallel to the y-axis depicted in FIG. 10C).

In an embodiment, each sense amp tier includes a third number N3 of sense amplifiers. In the example depicted in FIG. 10C, N3=6, and sense amp tier SA_{T0} includes sense amplifiers SA0, SA1, SA2, SA3, SA4, sense amp tier SA_{T1} includes sense amplifiers SA6, SA7, SA8, SA9, SA10 and SA11, sense amp tier SA_{T2} includes sense amplifiers SA12, SA12, SA14, SA15, SA16 and SA17, and sense amp tier SA_{T3} includes sense amplifiers SA18, SA19, SA20, SA21, SA22 and SA23. Persons of ordinary skill in the art will understand that each of sense amp tiers SA_{T0}, SA_{T1}, SA_{T2} and SA_{T3} may include more or fewer than the third number N3=6 sense amplifiers. In an embodiment, sense amplifiers SA0, SA1, . . . , SA23 are arranged horizontally (i.e., parallel to the x-axis depicted in FIG. 10C) within each sense amp tier.

In an embodiment, each bit line switch region includes a fourth number N4 of bit line switches. In the example depicted in FIG. 10C, N4=6, and bit line switch region BLS<0> includes bit line switches S0, S1, S2, S3, S4 and S5, bit line switch region BLS<1> includes bit line switches S6, S7, S8, S9, S10 and S11, bit line switch region BLS<2> includes bit line switches S12, S13, S14, S15, S16 and S17, and bit line switch region BLS<3> includes bit line switches S18, S19, S20, S21, S22 and S23.

As depicted in FIG. 10C, the third number N3=6 of sense amplifiers SA0, SA1, . . . , SA23 is equal to the fourth number N4 of bit line switches S0, S1, . . . , S23, and each bit line switch S0, S1, . . . , S23 is disposed adjacent a corresponding one of sense amplifiers SA0, SA1, . . . , SA23, respectively.

Persons of ordinary skill in the art will understand that each of bit line switch regions BLS<0>, BLS<1>, BLS<2> and BLS<3> may include more or fewer than the fourth number N4=6 of bit line switches. In an embodiment, bit line switches S0, S1, . . . , S23 are arranged horizontally (i.e., parallel to the x-axis depicted in FIG. 10C) within each bit line switch region.

In an embodiment, each of sense amp tiers SA_{T0}, SA_{T1}, SA_{T2} and SA_{T3} is adjacent a corresponding one of bit line switch regions BLS<0>, BLS<1>, BLS<2> and BLS<3>. In particular, sense amp tier SA_{T0} is adjacent bit line switch region BLS<0>, sense amp tier SA_{T1} is adjacent bit line switch region BLS<1>, sense amp tier SA_{T2} is adjacent bit line switch region BLS<2>, and sense amp tier SA_{T3} is adjacent bit line switch region BLS<3>.

In an embodiment, each bit line switch in a bit line switch region is coupled to a corresponding sense amplifier in the adjacent sense amp tier. In the example depicted in FIG. 10C, bit line switches S0, S1, S2, S3, S4 and S5 in bit line switch region BLS<0> are coupled to corresponding sense amplifiers SA0, SA1, SA2, SA3, SA4 and SA5, respectively, of adjacent sense amp tier SA_{T0}. Similarly, bit line switches S6, S7, S8, S9, S10 and S11 in bit line switch region BLS<1> are coupled to corresponding sense amplifiers SA6, SA7, SA8, SA9, SA10 and SA11, respectively, of adjacent sense amp tier SA_{T1}, and so on.

In an embodiment, each of bit lines 1012b₀, . . . , 1012b₂₃ in CBL Region 1026 is coupled to a corresponding cross bit line 1012b_{H0}, . . . , 1012b_{H23}, respectively, and each cross bit line 1012b_{H0}, . . . , 1012b_{H23} is coupled to a corresponding one of bit line switches S0, . . . , S23. In an embodiment, each bit line switch S0, . . . , S23 selectively couples a corresponding one of sense amplifiers SA0, . . . . SA23, respectively, to a corresponding one of cross bit lines 1012b_{H0} . . . 1012b_{H23}, respectively, and the corresponding coupled bit line 1012b₀ . . . , 1012b₂₃, respectively.

Thus, for example, bit line switch S0 selectively couples sense amplifier SA0 to cross bit line 1012b_{H0} and corresponding coupled bit line 1012b₀. Likewise, bit line switch S13 selectively couples sense amplifier SA13 to cross bit line 1012b_{H13} and corresponding coupled bit line 1012b₁₃. Similarly, bit line switch S23 selectively couples sense amplifier SA23 to cross bit line 1012b_{H23} and corresponding coupled bit line 1012b₂₃, and so on.

In an embodiment, the cross bit lines are divided into a fifth number N5 of cross bit line groups. In an embodiment, each cross bit line group is associated with a corresponding bit line switch region. In the example depicted in FIG. 10C, cross bit line groups CBL<0>, CBL<1>, CBL<2>, and CBL<3>, are associated with corresponding bit line switch regions BLS<0>, BLS<1>, BLS<2>, BLS<3>, respectively.

Thus, because there are a second number N2 of bit line switch regions, there are also a second number N2 of cross bit line groups, and fifth number N5 is equal to second number N2. In the example depicted in FIG. 10C, second number N2=4, and cross bit lines 1012b_{H0}, . . . , 1012b_{H23} are divided into second number N2=4 cross bit line groups CBL<0>, CBL<1>, CBL<2>, and CBL<3>.

Bit lines 1012b₀, . . . , 1212b₂₃ have a bit line pitch BL_{P}, and cross bit lines 1012b_{H0}, . . . , 1012b_{H23} have a CBL pitch CBL_{P}. In an embodiment, the bit line pitch BL_{P} is determined by characteristics of memory array 202. For example, the bit line pitch BL_{P} is determined by the number of memory holes in memory array 202, and the pitch of the memory holes. CBL Region 1026 includes a sixth number N6 of bit lines:

$$N 6 = \frac{{CBL}_{L}}{{BL}_{P}} \qquad ( 1 )$$

where CBLL is the length of CBL Region 1026. In the example diagram of FIG. 10C, N6=24. Persons of ordinary skill in the art will understand that CBL Region 1026 may include more or fewer than N6=24 bit lines.

In an embodiment, the CBL pitch CBL_{P} is determined based on a “CBL Budget” and the number of bit lines N_{BL} in the CBL region. The CBL Budget CBL_{B} is equal to:

$${CBL}_{B} = {SA}_{H} \times N 1 \qquad ( 2 )$$

where SA_{H} is the height of each sense amp tier and associated bit line switch region, and first number N1 is the number of sense amp tiers. In the example of FIG. 10C, N1=4.

The CBL pitch CBL_{P} is equal to the CBL budget CBL_{B} divided by the sixth number N6 of bit lines in CBL Region 1026:

$${CBL}_{P} = \frac{{CBL}_{B}}{N 6} \qquad ( 3 )$$

Thus, inserting Equation (2) in Equation (3), the CBL pitch CBL_{P} is equal to:

$${CBL}_{P} = \frac{{SA}_{H} \times N 1}{N 6} \qquad ( 4 )$$

where SA_{H} is the height of each sense amp tier and associated bit line switch region, first number N1 is the number of sense amp tiers, and sixth number N6 is the number of bit lines in CBL Region 1026.

With advances in technology, the first number N1 of sense amp tiers tends to decrease and the height SA_{H} of each sense amp tier and associated bit line switch region also tends to decrease. As a result, from Equations (2) and (3), if the same layout strategy described above is used the CBL budget CBL_{B} will decrease, and the CBL pitch CBL_{P} also will decrease. Decreasing the CBL pitch CBL_{P} will require more expensive processing to achieve a finer pitch. However, it is preferable to use the least expensive process technology to reduce the cost of the memory device.

Technology is described for relaxing (i.e., increasing) the CBL pitch CBL_{P} to reduce the CBL process cost. In the example depicted in FIG. 10C, each of cross bit line groups CBL<0>, CBL<1>, CBL<2>, and CBL<3> includes a seventh number N7 of cross bit lines, where N7 is equal to:

$$N 7 = \frac{N 6}{N 2} \qquad ( 5 )$$

where sixth number N6 is the number of bit lines in CBL Region 1026 and the second number N2 is the number of bit line switch regions BLS<0>, BLS<1>, BLS<2>, BLS<3> and associated corresponding cross bit line groups CBL<0>, CBL<1>, CBL<2>, CBL<3> in sense amp region 920.

In the example depicted in FIG. 10C, N6=24 and N2=4, so each cross bit line group CBL<0>, CBL<1>, CBL<2>, CBL<3> includes N7=N6/N2=6 cross bit lines. Technology is described for increasing CBL pitch CBL_{P} by increasing the second number N2 of cross bit line groups without increasing the first number N1 of sense amp tiers.

In addition, as depicted in FIG. 10C, cross bit line groups CBL<0>, CBL<1>, CBL<2>, CBL<3> and cross bit lines 1012b_{H0}, . . . , 1012b_{H23} are routed within a region having a vertical height equal to the CBL budget CBL_{B}, which is equal to the vertical height of sense amp region 920. Technology is described for increasing CBL pitch CBL_{P} by effectively increasing the CBL budget CBL_{B} by routing cross bit line groups and cross bit lines in a region that exceeds the vertical height of sense amp region 920a.

In addition, as depicted in FIG. 10C, the second number N2 of bit line switch regions BLS<0>, BLS<1>, BLS<2>, BLS<3> is equal to the first number N1 of sense amp tiers (i.e., N2=N1=4). Technology is described for increasing CBL pitch CBL_{P} by increasing the second number N2 of bit line switch regions without increasing the first number N1 of sense amp tiers (e.g., N2>N1). In an embodiment, the second number N2 of bit line switch regions is two more than the first number N1 of sense amp tiers (i.e., N2=N1+2).

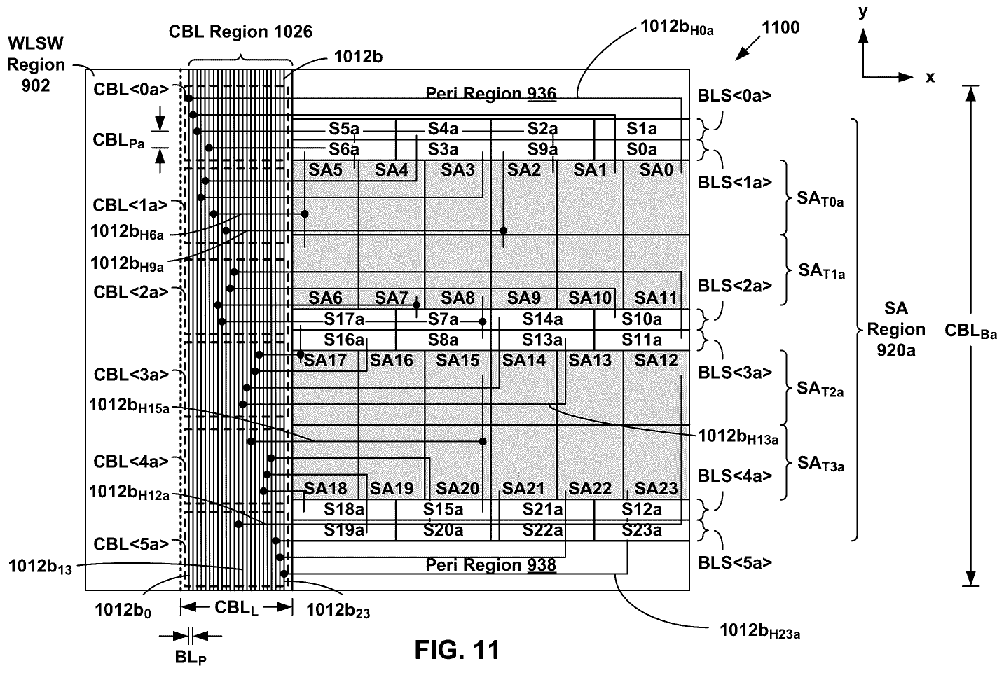

FIG. 11 is a top view of a portion 1100 of section 958 of control die 240. In particular, FIG. 11 is a detailed view of an alternative layout of left portion of FIG. 10A. Portion 1100 includes a sense amp region 920a that includes first number N1=4 sense amp tiers SA_{T0a}, SA_{T1a}, SA_{T2a} and SA_{T3a}, and each sense amp tier includes third number N3=6 sense amplifiers.

In particular, sense amp tier SA_{T0a} includes sense amplifiers SA0, SA1, SA2, SA3, SA4 and SA5, sense amp tier SA_{T1a} includes sense amplifiers SA6, SA7, SA8, SA9, SA10 and SA11, sense amp tier SA_{T2a} includes sense amplifiers SA12, SA12, SA14, SA15, SA16 and SA17, and sense amp tier SA_{T3a} includes sense amplifiers SA18, SA19, SA20, SA21, SA22 and SA23.

In an embodiment, sense amp region 920a includes second number N2=(N1+2)=6 bit line switch regions BLS<0a>, BLS<1a>, . . . , BLS<5a>. That is in contrast to sense amp region 920 of FIG. 10C, which included a same number of bit line switch regions as sense amp tiers (i.e., N2=N1), sense amp region 920a includes two additional bit line switch regions than sense amp tiers (i.e., N2=N1+2).

In the embodiment of FIG. 10C, each of bit line switch regions BLS<0>, BLS<1>, BLS<2> and BLS<3> is adjacent a corresponding one of sense amp tiers SA_{T0}, SA_{T1}, SA_{T2} and SA_{T3}. In contrast, in the embodiment of FIG. 11 there are more bit line switch regions BLS<0a>, BLS<1a>, . . . , BLS<5a>than sense amp tiers SA_{T0}, SA_{T1}, SA_{T2} and SA_{T3}. As a result, two of bit line switch regions BLS<0a>, BLS<1a>, . . . , BLS<5a> are not disposed adjacent a corresponding one of sense amp tiers SA_{T0}, SA_{T1}, SA_{T2} and SA_{T3}.

In particular, sense amp tier SA_{T0a} is adjacent bit line switch region BLS<0a>, sense amp tier SA_{T1a} is adjacent bit line switch region BLS<2a>, sense amp tier SA_{T2a} is adjacent bit line switch region BLS<3a>, and sense amp tier SA_{T3a} adjacent bit line switch region BLS<4a>. In contrast, bit line switch region BLS<0a> and bit line switch region BLS<5a> are not disposed adjacent a corresponding one of sense amp tiers SA_{T0}, SA_{T1}, SA_{T2} and SA_{T3}.

In the embodiment of FIG. 10C, each of bit line switch regions BLS<0>, BLS<1>, BLS<2>, BLS<3> includes a fourth number N4=6 bit line switches, and fourth number N4 is equal to the third number N3=6 of sense amp circuits in each sense amp tier. In contrast, in the embodiment of FIG. 11, each of bit line switch regions BLS<0a>, BLS<1a>, BLS<2a>, BLS<3a>, BLS<4a>, BLS<5a> includes a fourth number N4=4 bit line switches, and fourth number N4 is less than third number N3=6.

In the embodiment of FIG. 11, each bit line switch SA0a, SA1a, . . . , SA23a is coupled to a corresponding one of sense amplifiers SA0, SA1, . . . , SA23. For example, bit line switch region BLS<0a> includes bit line switches S1a, S2a, S4a and S5a coupled to a corresponding one of sense amplifiers SA1, SA2, SA4 and SA5, respectively.

Similarly, bit line switch region BLS<1a> includes bit line switches S0a, S9a, S3a and S6a coupled to a corresponding one of sense amplifiers SA0, SA9, SA3 and SA6, respectively, bit line switch region BLS<2a> includes bit line switches S10a, S14a, S7a and S17a coupled to a corresponding one of sense amplifiers SA10, SA14, SA7 and SA17, respectively, bit line switch region BLS<3a> includes bit line switches S11a, S13a, S8a and S16a coupled to a corresponding one of sense amplifiers SA11, SA13, SA8 and SA16, respectively, bit line switch region BLS<4a> includes bit line switches S12a, S21a, S15a and S18a coupled to a corresponding one of sense amplifiers SA12, SA21, SA15 and SA18, respectively, and bit line switch region BLS<5a> includes bit line switches S23a, S22a, S20a and S19a coupled to a corresponding one of sense amplifiers SA23, SA22, SA20 and SA19, respectively.

In an embodiment, each of bit lines 1012b₀, . . . , 1012b₂₃ in CBL Region 1026 is coupled to a corresponding cross bit line 1012b_{H0a}, . . . , 1012b_{H23a}, respectively, and each cross bit line 1012b_{H0a}, . . . , 1012b_{H23a} is coupled to a corresponding one of bit line switches S0a, . . . , S23a. In an embodiment, each bit line switch S0a, . . . , S23a selectively couples a corresponding one of sense amplifiers SA0, . . . , SA23, respectively, to a corresponding one of cross bit lines 1012b_{H0a}, . . . , 1012b_{H23a}, respectively, and the corresponding coupled bit line 1012b₀, . . . , 1012b₂₃, respectively.

Thus, for example, bit line switch S0a selectively couples sense amplifier SA0 to cross bit line 1012b_{H0a} and corresponding coupled bit line 1012b₀. Likewise, bit line switch S13a selectively couples sense amplifier SA13 to cross bit line 1012b_{H13a} and corresponding coupled bit line 1012b₁₃ₐ. Similarly, bit line switch S23a selectively couples sense amplifier SA23 to cross bit line 1012b_{H23a} and corresponding coupled bit line 1012b₂₃, and so on.

In an embodiment, each cross bit line group is associated with a corresponding bit line switch region. In the example depicted in FIG. 11, cross bit line groups CBL<0a>, CBL<1a>, CBL<2a>, CBL<3a>, CBL<4a> and CBL<5a>, are associated with corresponding bit line switch regions BLS<0a>, BLS<1a>, BLS<2a>, BLS<3a>, BLS<4a>, BLS<5a>, respectively.

In an embodiment, the cross bit lines are divided into the second number N2=6 of cross bit line groups CBL<0a>, CBL<1a>, CBL<2a>, CBL<3a>, CBL<4a> and CBL<5a>. In the embodiment of FIG. 11, cross bit lines 1012b_{H0a}, . . . , 1012b_{H23a} are divided into the second number N2=6 cross bit line groups CBL<0a>, CBL<1a>, CBL<2a>, CBL<3a>, CBL<4a> and CBL<5a>.

In the example depicted in FIG. 10C, each of cross bit line groups CBL<0>, CBL<1>, CBL<2>, and CBL<3> includes the seventh number N7=N6/N2 cross bit lines. In the example depicted in FIG. 10C, N6=24 and N2=4, so each of cross bit line groups CBL<0>, CBL<1>, CBL<2>, and CBL<3> includes 24/4=6 cross bit lines. In contrast, in the example depicted in FIGS. 11, N6=24 and N2=6, so each of cross bit line groups CBL<a0>, CBL<1a>, CBL<2a>, CBL<3a>, CBL<4a> and CBL<5a> includes 24/6=4 cross bit lines.

In the example depicted in FIG. 10C, cross bit line groups CBL<0>, CBL<1>, CBL<2>, and CBL<3> and cross bit lines 1012b_{H0}, . . . , 1012b_{H23} are routed within a region having a vertical height equal to the CBL budget CBL_{B}, which is equal to the vertical height of sense amp region 920. That is, all cross bit lines 1012b_{H0}, . . . , 1012b_{H23} are routed over sense amp tiers SA_{T0}, . . . , SA_{T3}.

In contrast, in the embodiment of FIG. 11 cross bit line groups CBL<0a>, CBL<1a>, CBL<2a>, CBL<3a>, CBL<4a> and CBL<5> and cross bit lines 1012b_{H0a}, . . . , 1012b_{H23a} are routed in a region that exceeds the vertical height of sense amp region 920a. In this regard, the cross bit line budget is effectively increased.

In an embodiment, a first portion of cross bit lines 1012b_{H0a}, . . . , 1012b_{H23a} are routed over sense amp tiers SA_{T0a}, . . . , SA_{T3a}, and a second portion of cross bit lines 1012b_{H0a}, . . . , 1012b_{H23a} are routed over circuits other than sense amp tiers SA_{T0a}, . . . , SA_{T3a}. For example, cross bit lines 1012b_{H0a} and 1012b_{H1a} are routed over Peri Region 936, and cross bit lines 1012b_{H22a} and 1012b_{H23a} are routed over Peri Region 938.

In this regard, the cross bit line budget CBL_{Ba} of portion 100 of FIG. 11 is effectively larger than the cross bit line budget CBL_{B} of portion 1030 of FIG. 10C (i.e., CBL_{Ba}>CBL_{B}). From Equation (3) above, the CBL pitch CBL_{Pa} of portion 1100 of FIG. 11 is:

$${CBL}_{Pa} = \frac{{CBL}_{Ba}}{N 6} \qquad ( 6 )$$

where sixth number N6 is the number of bit lines in CBL Region 1024 (24). Comparing Equation (3) with Equation (6), because CBL_{Ba}>CBL_{B} and the sixth number N6=24 in both embodiments, the CBL pitch CBL_{Pa}>CBL_{P}.

Indeed, portion 1100 of FIG. 11 includes a same number of bit line switch regions (N2=6) used by a conventional N1=6 tier sense amp region, but only includes N1=4 sense amp tiers. Without wanting to be bound by any particular theory, it is believed that the disclosed technology provides the benefit a 6-tier CBL budget CBL_{Ba} for a 4-tier sense amp region.

In the embodiment of FIG. 11, some of cross bit lines 1012b_{H0a}, . . . , 1012b_{H23a} are routed through another sense amp tier, For example, cross bit line 1012b_{H6a} is routed to sense amplifier SA6 (in sense amp tier SA_{T1a}) through sense amp tier SA_{T0a} to bit line switch S6a. Similarly, cross bit line 1012b_{H9a} is routed to sense amplifier SA9 (in sense amp tier SA_{T1a}) through sense amp tier SA_{T0a} to bit line switch S9a. Likewise, cross bit line 1012b_{H15a} is routed to sense amplifier SA15 (in sense amp tier SA_{T2}a) through sense amp tier SA_{T3a} to bit line switch S15a. Also, cross bit line 1012b_{H12a} is routed to sense amplifier SA12 (in sense amp tier SA_{T2a}) through sense amp tier SA_{T3a} to bit line switch S12a. Cross bit lines that are routed through another sense amp tier are referred to herein as “thru bit lines.”

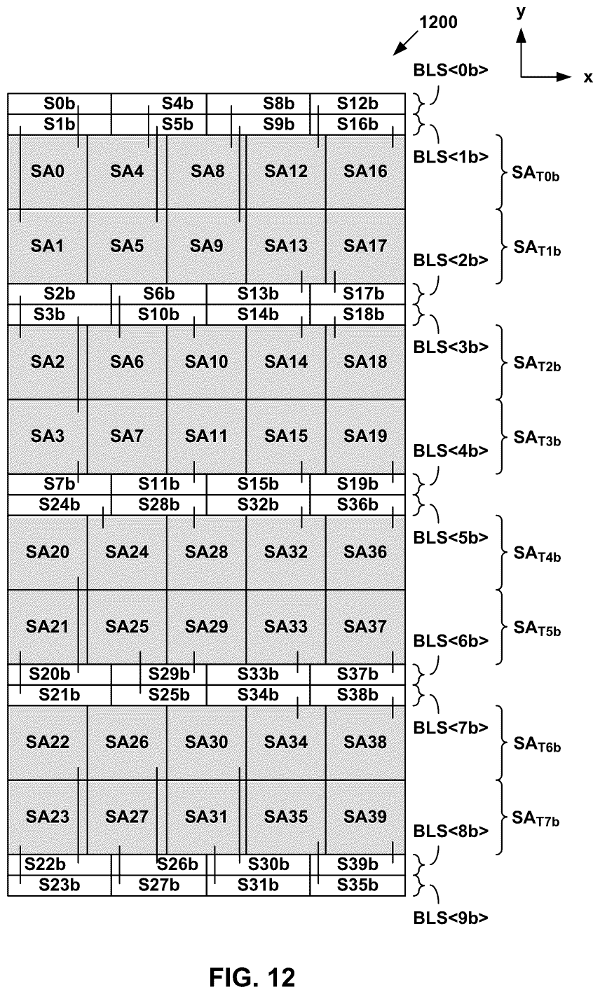

FIG. 12 is a simplified view of another example layout of a portion 1200 of the control die of FIG. 10A. The layout of portion 1200 is similar to the layout of portion 1100 of FIG. 11, but is for an N1=8 sense amp tiers (SA_{T0b}, SA_{T1b}, SA_{T7b}) with N2=N1+2=10 bit line switch regions (BLS<0b>, BLS<1b>, . . . , BLS9b>. To avoid overcrowding the drawing, cross bit line groups CBL<0b>, CBL<1b>, . . . , CBL9b>, bit lines 1012, cross bit lines, and other elements are not shown in FIG. 12.

In the example of FIG. 12, each sense amp tier SA_{T0b}, SA_{T1b}, . . . . SA_{T7b} includes third number N3=5 sense amplifiers, and each bit line switch region BLS<0b>, BLS<1b>, . . . , BLS9b> includes N4=4 bit line switches. In particular, sense amp tier SA_{T0b} includes sense amplifiers SA0, SA4, SA8, SA12, and SA16, and soon, and bit line switch region BLS<0b> includes bit line switches S0b, S4b, S8b and S12b, and so on. Each of bit line switches S0b, S1b, . . . , S39b is coupled to a corresponding one of sense amplifiers SA0, SA2, . . . , SA39, respectively.

As in the example layout of portion 1100 of FIG. 11, example layout of portion 1200 includes thru bit lines that are routed through another sense amp tier. In particular, sense amplifiers SA1, SA3, SA5, SA9, SA20, SA22, SA26 and SA30 are coupled via thru bit lines to bit line switches S1b, S3b, S5b, S9b, S20b, S22b, S26b and S30b, respectively. Each of the thru bit lines consumes a vertical track. Absent some remediation technique, the thru bit lines would conflict with other routing tracks in the layout. In the illustrated example, there are a maximum of 3 thru bit lines for every 5 sense amplifier columns, and average of 3/5=0.6 tracks.

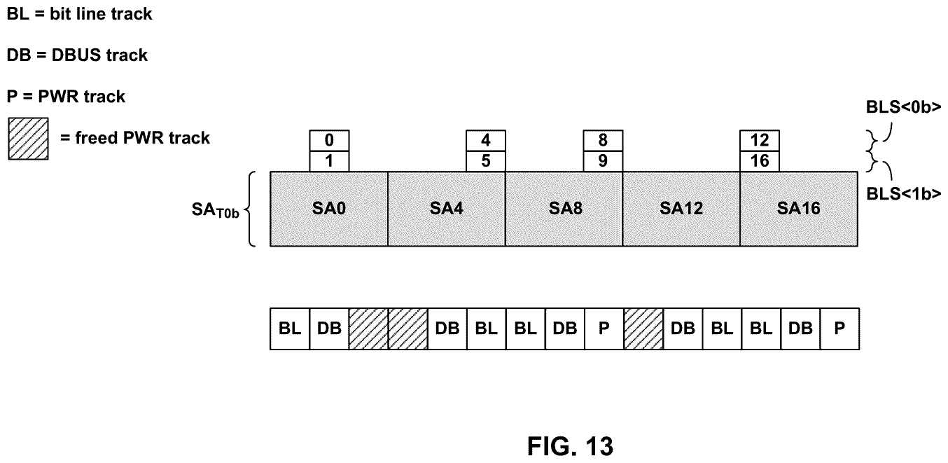

In an embodiment, additional vertical tracks are secured for routing thru bit lines. In particular, FIG. 13 is a simplified diagram of the sense amp tier SA_{T0b} and bit line switch regions BLS<0b> and BLS<1b> of FIG. 12. To avoid overcrowding the drawing, bit line switches S0b, S1b, S4b, S5b, S8b, S9b, S12 and S16b are identified as 0, 1, 4, 5, 8, 9, 12 and 16, respectively. Depicted beneath sense amp tier SA_{T0b} is a cross-sectional view of tracks disposed above sense amp tier SA_{T0b} and bit line switch regions BLS<0b> and BLS<1b>. In an embodiment, every six tracks include two power lines (e.g., VDD, VSS) that are shared between all of the sense amps. As a result, one of the power lines can be removed from a track. The tracks shown in cross-hatched shading are tracks from which powerlines have been removed. These shaded tracks can then be used for routing thru bit lines.

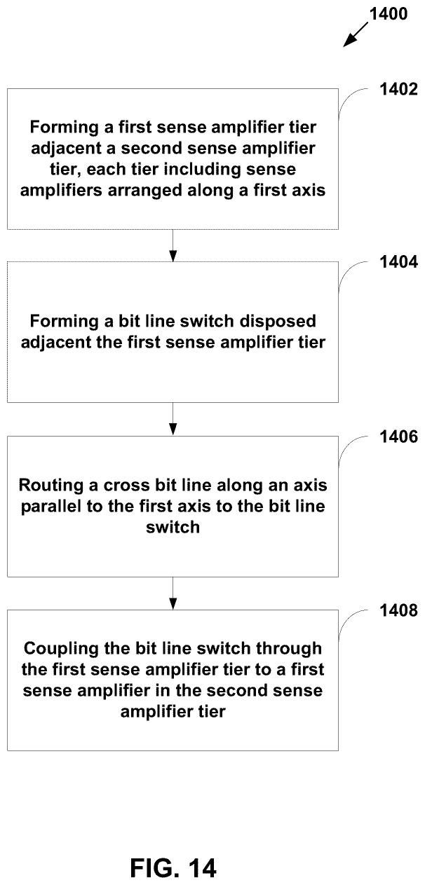

FIG. 14 is a flow diagram of an embodiment of a process 1400 for fabricating a control die that includes circuits for controlling a memory die including a three dimensional non-volatile memory array. At step 1402, a first sense amplifier tier is formed adjacent a second sense amplifier tier. In an embodiment, the first sense amplifier tier and second sense amplifier tier each include sense amplifiers arranged along a first axis. At step 1404, a bit line switch is formed and disposed adjacent the first sense amplifier tier. At step 1406, a cross bit line is routed along an axis parallel to the first axis to the bit line switch. At step 1408, the bit line switch is coupled through the first sense amplifier tier to a first sense amplifier in the second sense amplifier tier.

One embodiment includes an apparatus that includes a three dimensional non-volatile memory array that has non-volatile memory cells, and a control circuit below the three dimensional non-volatile memory array and configured to control the three dimensional non-volatile memory array. The control circuit includes a first number of sense amplifier tiers, each having sense amplifiers arranged along a first axis, a second number of bit line switch regions, each having bit line switches, each bit line switch coupled to a corresponding one of the sense amplifiers, the second number greater than the first number, and a plurality of cross bit lines routed along an axis parallel to the first axis and arranged along a second axis perpendicular to the first axis, each cross bit line coupled to a corresponding one of the bit line switches. Each bit line switch is configured to selectively couple a corresponding one of the cross bit lines to a corresponding one of the sense amplifiers.

One embodiment includes a system that includes a control die including a control circuit for a three dimensional non-volatile memory array. The control circuit including a sense amplifier region and a peripheral region. The sense amplifier region includes sense amplifiers arranged along a first axis and cross bit lines routed along an axis parallel to the first axis and arranged along a second axis perpendicular to the first axis, each cross bit line coupled to a corresponding one of the sense amplifiers. The peripheral region includes circuits other than sense amplifiers, and is disposed separate from the sense amplifier region. A first plurality of the cross bit lines are routed above the peripheral region.

One embodiment includes a method that includes fabricating a control die comprising circuits for controlling a memory die including a three dimensional non-volatile memory array by: forming a first sense amplifier tier adjacent a second sense amplifier tier, each comprising sense amplifiers arranged along a first axis, forming a bit line switch disposed adjacent the first sense amplifier tier, routing a cross bit line along an axis parallel to the first axis to the bit line switch, and coupling the bit line switch through the first sense amplifier tier to a first sense amplifier in the second sense amplifier tier.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more others parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

1. An apparatus comprising:
a three dimensional non-volatile memory array that includes non-volatile memory cells; and
a control circuit below the three dimensional non-volatile memory array and configured to control the three dimensional non-volatile memory array, the control circuit including:
a first number of sense amplifier tiers, each comprising sense amplifiers arranged along a first axis;
a second number of bit line switch regions, each comprising bit line switches, each bit line switch coupled to a corresponding one of the sense amplifiers, the second number greater than the first number; and
a plurality of cross bit lines routed along an axis parallel to the first axis and arranged along a second axis perpendicular to the first axis, each cross bit line coupled to a corresponding one of the bit line switches,
wherein each bit line switch is configured to selectively couple a corresponding one of the cross bit lines to a corresponding one of the sense amplifiers.

2. The apparatus of claim 1, wherein each sense amplifier tier includes a third number of sense amplifiers, each bit line switch region includes a fourth number of bit line switches, and the third number does not equal the fourth number.

3. The apparatus of claim 2, wherein the fourth number is less than the fourth number.

4. The apparatus of claim 1, wherein:
a first of the bit line switches is coupled to a first sense amplifier;
a second of the bit line switches is coupled to a second sense amplifier;
the first bit line switch is disposed adjacent the first sense amplifier; and
the second bit line switch is not disposed adjacent the second sense amplifier.

5. The apparatus of claim 1, wherein:
a first of the bit line switches is coupled to a first one of the sense amplifiers disposed in an adjacent sense amplifier tier; and
a second of the bit line switches is coupled to a second one of the sense amplifiers disposed in a non-adjacent sense amplifier tier.

6. The apparatus of claim 1, wherein one of the bit line switches is coupled via a routing through a first sense amplifier tier to a sense amplifier disposed in a second sense amplifier tier.

7. The apparatus of claim 1, wherein fewer than all of the plurality of cross bit lines are routed above the sense amplifiers.

8. The apparatus of claim 1, wherein the control circuit further comprises a first region comprising the sense amplifier tiers and the bit line switch regions, and a second region adjacent the first region, wherein some of the cross bit lines are routed above the second region.

9. The apparatus of claim 1, wherein the control circuit further comprises a plurality of bit lines comprising a bit line pitch, each of the bit line coupled to a corresponding one of the cross bit lines, the cross bit lines comprising a cross bit line pitch greater than the bit line pitch.

10. The apparatus of claim 1, further comprising:
a memory die comprising the three dimensional non-volatile memory array and a first set of bond pads connected to the three dimensional non-volatile memory array; and
a control die comprising the control circuit and a second set of bond pads, the first set of bond pads connected to the second set of bond pads.

11. The apparatus of claim 1, wherein the second number is two more than the first number.

12. A system comprising:
a control die comprising a control circuit for a three dimensional non-volatile memory array, the control circuit comprising:
a sense amplifier region comprising sense amplifiers arranged along a first axis and cross bit lines routed along an axis parallel to the first axis and arranged along a second axis perpendicular to the first axis, each cross bit line coupled to a corresponding one of the sense amplifiers; and
a peripheral region comprising circuits other than sense amplifiers, the peripheral region disposed separate from the sense amplifier region,
wherein a first plurality of the cross bit lines are routed above the peripheral region.

13. The system of claim 12, wherein the sense amplifier region further comprises bit line switches, each coupled to a corresponding one of the sense amplifiers and a corresponding one of the cross bit lines.

14. The system of claim 12, wherein each bit line switch is configured to selectively couple a corresponding one of the cross bit lines to a corresponding one of the sense amplifiers.

15. The system of claim 12, wherein the sense amplifiers are disposed in a first number of sense amplifier tiers, and the bit line switches are disposed in a second number of bit line switch regions, the second number greater than the first number.

16. The system of claim 12, wherein the sense amplifier region further comprises:
a sense amplifier tier comprising a third number of the sense amplifiers; and
a bit line switch region comprising a fourth number of the bit line switches,
wherein and the third number is greater than the fourth number.

17. The system of claim 12, wherein a second plurality of the cross bit lines are routed above the sense amplifier region.

18. The system of claim 12, further comprising a memory die comprising the three dimensional non-volatile memory array and a first set of bond pads connected to the three dimensional non-volatile memory array and to a second set of bond pads on the control die.

19. A method comprising:
fabricating a control die comprising circuits for controlling a memory die comprising a three dimensional non-volatile memory array by:
forming a first sense amplifier tier adjacent a second sense amplifier tier, each comprising sense amplifiers arranged along a first axis;
forming a bit line switch disposed adjacent the first sense amplifier tier;
routing a cross bit line along an axis parallel to the first axis to the bit line switch; and
coupling the bit line switch through the first sense amplifier tier to a first sense amplifier in the second sense amplifier tier.

20. The method of claim 19, further comprising coupling the bit line switch to the first sense amplifier through a track configured to route a power line signal.
